(19) United States
(12) Patent Application Publication
(10) Pub. No.: US 2023/0173637 A1
(43) Pub. Date: Jun. 8, 2023

(54) POLISHING PAD, POLISHING UNIT, POLISHING DEVICE, AND METHOD FOR MANUFACTURING POLISHING PAD

(71) Applicant: FUJIBO HOLDINGS, INC., Tokyo (JP)

(72) Inventors: Teppei TATENO, Ehime (JP); Ryuma MATSUOKA, Ehime (JP); Hiroshi KURIHARA, Ehime (JP); Satsuki NARUSHIMA, Ehime (JP); Yamato TAKAMIZAWA, Ehime (JP)

(21) Appl. No.: 17/912,937

(22) PCT Filed: Mar. 19, 2021
(86) PCT No.: PCT/JP2021/011502

§ 371 Date: Sep. 20, 2022

(30) Foreign Application Priority Data
Mar. 26, 2020 (JP) 2020-056515
Mar. 26, 2020 (JP) 2020-056516
Mar. 26, 2020 (JP) 2020-056517

(51) Int. Cl. B24B 37/22

(52) U.S. Cl. CPC B24B 37/22

(57) ABSTRACT

Provided is a polishing unit that can reduce penetration of a polishing slurry into a base material layer and that can prevent impairment in polishing performance. A polishing unit (10a) in accordance with a first aspect of the present invention includes: a polishing pad (100a) that includes a polishing layer (101) and a base material layer (103); and a surface plate (150), the base material layer (103) having a diameter smaller than a diameter of the polishing layer (101) and greater than a diameter of the surface plate (150).

### TECHNICAL FIELD

The present invention relates to a polishing pad, a polishing unit, a polishing device, and a method for manufacturing a polishing pad.

### BACKGROUND ART

Typically, polishing pads have a laminate structure in which a polishing layer configured to come into contact with a material to be polished (i.e., a polished material) is bonded, via a double-sided adhesive tape, to a base material layer which is configured to support the polishing layer and which is identical in planar shape and size to the polishing layer. In a polishing step, polishing is carried out in such a manner that a polishing slurry is fed to a center portion of the polishing pad and the polished material and the polishing pad are caused to move relative to each other. During this, the polishing slurry may intrude into the inside through an outer peripheral side surface of the base material layer, and accordingly the double-sided adhesive tape may be separated from the base material layer, disadvantageously. Patent Literature 1 discloses, as a technique for solving this problem, a polishing pad including a polishing layer and a lower layer which has been subjected to a water-repellent treatment. Patent Literature 2 discloses a polishing pad including an underlying layer which is smaller in size than a pad body and which has a peripheral side surface provided with a waterproof layer.

### Citation List

### Patent Literature

Patent Literature 1 Japanese Patent Application Publication Tokukai No. 2004-311722
Patent Literature 2 Japanese Patent Application Publication Tokukai No. 2002-36097

### SUMMARY OF INVENTION

### Technical Problem

However, the invention disclosed in Patent Literature 1 involves a problem that the adhesiveness between the lower layer and the double-sided adhesive tape may be deteriorated by the water-repellent treatment conducted on the surface of the lower layer. Meanwhile, the invention disclosed in Patent Literature 2 involves a disadvantage that, in bonding of the polishing pad to a surface plate of a polishing device, the underlying layer that is to be in contact with the surface plate cannot be visually observed, since the pad body is larger in size than the underlying layer. This may lead to misalignment of the polishing pad with the surface plate in bonding of the polishing pad to the surface plate. Carrying out polishing in the state where the polishing pad is misaligned with the surface plate may result in impairment in the polishing performance due to shifting of the center of gravity, disadvantageously.

Furthermore, according to the invention disclosed in Patent Literature 2, if a double-sided adhesive tape is used as the waterproof layer, the polishing pad is hardly brought into complete tight contact with the outer peripheral side surface of the underlying layer. This is troublesome in terms of manufacturing. If an elastomer or a rubber is applied as the waterproof layer, a void formed in the underlying layer cannot be buried completely in some cases. This may allow a polishing slurry to penetrate into the underlying layer through the unburied void, disadvantageously.

Moreover, according to the invention disclosed in Patent Literature 2, if an elastomer or a rubber is applied as the waterproof layer, a void formed in the underlying layer cannot be buried completely. In addition, a force applied to the polishing pad in bonding of the polishing pad to the polishing device may cause cracking in the waterproof layer. In such cases, the polishing slurry may pass through the unburied void and the cracking made as a result of failing to withstand bending, so as to penetrate into the underlying layer, disadvantageously.

A first aspect of the present invention has an object to provide a polishing pad and a polishing unit that can reduce penetration of a polishing slurry into a base material layer and that can prevent deterioration of the polishing performance. A second aspect of the present invention has an object to provide a polishing pad that can reduce penetration of a polishing slurry into a base material layer even if the base material layer has not been subjected to a water-repellent treatment. A third aspect of the present invention has an object to provide (i) a polishing pad that has high durability against bending and that can reduce penetration of a polishing slurry into a base material layer and (ii) a method for manufacturing the polishing pad.

### Solution to Problem

In order to attain the above object, a polishing pad in accordance with a first aspect of the present invention includes: a polishing layer; a first adhesive layer; a base material layer including a nonwoven fabric; and a second adhesive layer, the polishing layer, the first adhesive layer, the base material layer, and the second adhesive layer being laminated in this order so as to be arranged concentrically, the base material layer having a diameter smaller than a diameter of the polishing layer.

In order to attain the above object, a polishing unit in accordance with a first aspect of the present invention includes: a polishing pad; and a surface plate, wherein: the polishing pad includes a polishing layer, a first adhesive layer, a base material layer including a nonwoven fabric, and a second adhesive layer which are laminated in this order; the polishing pad is bonded to the surface plate via the second adhesive layer; the base material layer has a diameter that is smaller than a diameter of the polishing layer and that is greater than a diameter of the surface plate; and when seen in plan view from a side of the surface plate, the base material layer is disposed inward of the polishing layer and the surface plate is disposed inward of the base material layer.

In order to attain the above object, a polishing pad in accordance with a second aspect of the present invention includes: a polishing layer; a base material layer including a nonwoven fabric; a first adhesive layer; and a frame having a ring shape, the polishing layer and the base material layer being bonded to each other via the first adhesive layer, the base material layer having a diameter smaller than a diameter of the polishing layer, the frame having a ring shape covering an outer peripheral side surface of the base material layer.

In order to attain the above object, a polishing pad in accordance with a third aspect of the present invention includes: a polishing layer; a base material layer including a nonwoven fabric; and a first adhesive layer, the polishing layer and the base material layer being bonded to each other via the first adhesive layer, the base material layer having a diameter smaller than a diameter of the polishing layer, a sealing part made of a material containing a photocurable resin covering (i) an outer peripheral side surface of the base material layer and (ii) an area of a surface of the adhesive layer which surface is adjacent to the base material layer, the area being not in contact with the base material layer, a loss modulus E″(S) at 40° C. of the sealing part, measured in a bending mode in a dynamic mechanical analysis at a frequency of 0.16 Hz, being 1 to 10 times greater than a loss modulus E″(P) of the polishing layer.

In order to attain the above object, a method for manufacturing a polishing pad in accordance with an aspect of the present invention is a method for manufacturing a polishing pad that includes a polishing layer and a base material layer, the method including: a laminating step of obtaining a laminate pad that includes a polishing sheet, a first adhesive sheet, a base material sheet including a nonwoven fabric, and a second adhesive sheet which are laminated in this order; a cutting step of cutting the laminate pad by inserting a cutting die into the laminate pad from a side of the second adhesive sheet, the cutting die including (i) a substrate, (ii) a cutting blade provided on the substrate and configured to cut the laminate pad into a shape of the polishing layer, and (iii) a slitting blade provided on the substrate and configured to make, in the laminate pad, a slit having a shape of the base material layer, the slitting blade being disposed inward of the cutting blade, the cutting blade having a height not less than a thickness of the laminate pad, the slitting blade having a height not less than a sum of a thickness of the base material sheet and a thickness of the second adhesive sheet, a difference in height between the cutting blade and the slitting blade being equal to a thickness of the polishing sheet or to a sum of the thickness of the polishing sheet and a thickness of the first adhesive sheet; and a removing step of removing, from the laminate pad having been cut into the shape of the polishing layer, portions of the base material sheet and the second adhesive sheet which portions are outward of the slit, so as to obtain the polishing pad.

### Advantageous Effects of Invention

In accordance with an aspect of the present invention, it is possible to provide a polishing unit that can reduce penetration of a polishing slurry into a base material layer and that can prevent deterioration of the polishing performance. In accordance with an aspect of the present invention, it is possible to provide a polishing pad that can reduce penetration of a polishing slurry into a base material layer even if the base material layer has not been subjected to a water-repellent treatment. In accordance with an aspect of the present invention, it is possible to provide (i) a polishing pad that has high durability against bending and that can reduce penetration of a polishing slurry into a base material layer and (ii) a method for manufacturing the polishing pad.

### BRIEF DESCRIPTION OF DRAWINGS

FIG. 1 is a view schematically illustrating a configuration of a polishing device in accordance with Embodiment 1 of the present invention.

FIG. 2 is a cross-sectional view illustrating a configuration of a polishing unit in accordance with Embodiment 1 of the present invention.

FIG. 3 is a top view of a cutting die used in a method for manufacturing a polishing pad in accordance with Embodiment 1 of the present invention.

FIG. 4 is a cross-sectional view of the cutting die used in the method for manufacturing the polishing pad in accordance with Embodiment 1 of the present invention.

FIG. 5 is a view schematically illustrating the method for manufacturing the polishing pad in accordance with Embodiment 1 of the present invention.

FIG. 6 is a cross-sectional view illustrating a configuration of a polishing unit in accordance with Embodiment 2 of the present invention.

FIG. 7 is a top view of a die used in a method for manufacturing a polishing pad in accordance with Embodiment 2 of the present invention.

FIG. 8 is a cross-sectional view of the die used in the method for manufacturing the polishing pad in accordance with Embodiment 2 of the present invention.

FIG. 9 is a view schematically illustrating a bonding step in the method for manufacturing the polishing pad in accordance with Embodiment 2 of the present invention.

FIG. 10 is a cross-sectional view illustrating a configuration of a polishing pad in accordance with Embodiment 3 of the present invention.

FIG. 11 is a cross-sectional view illustrating a die used in a method for manufacturing the polishing pad in accordance with Embodiment 3 of the present invention.

FIG. 12 is a view schematically illustrating a bonding step in the method for manufacturing the polishing pad in accordance with Embodiment 3 of the present invention.

FIG. 13 is a cross-sectional view illustrating a configuration of a polishing unit in accordance with Embodiment 4 of the present invention.

FIG. 14 is a view schematically illustrating a method for manufacturing a polishing pad in accordance with Embodiment 4 of the present invention.

FIG. 15 is a view schematically illustrating an applying step in the method for manufacturing the polishing pad in accordance with Embodiment 4 of the present invention.

### DESCRIPTION OF EMBODIMENTS

The following will give a detailed description of embodiments of the present invention.

### Embodiment 1

### Polishing Device

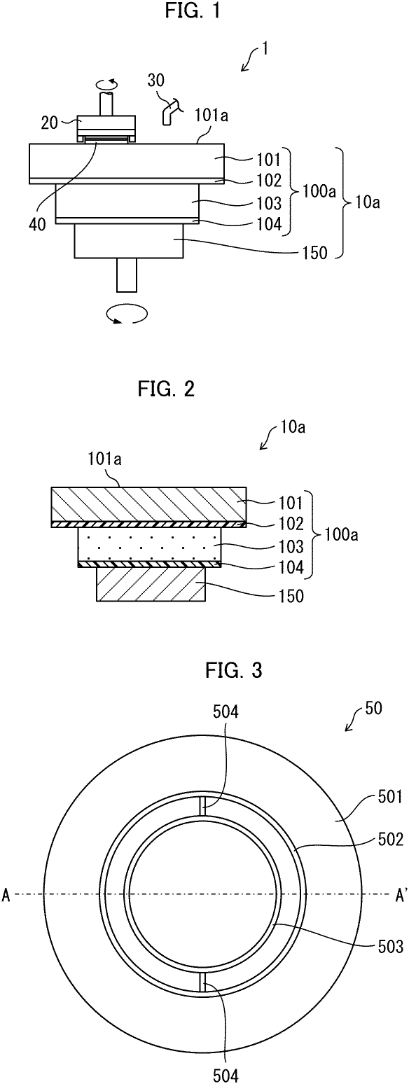

FIG. 1 is a view schematically illustrating a configuration of a polishing device in accordance with Embodiment 1. As shown in FIG. 1, the polishing device 1 includes a polishing unit 10a, a holding unit 20, and a polishing slurry feeding section 30.

The polishing unit 10a is a unit for polishing a polished material 40 held by the holding unit 20. The holding unit 20 is a unit, provided above the polishing unit 10a, for holding the polished material 40. The polishing slurry feeding section 30 is a member for feeding a polishing slurry onto a polishing surface 101a, which is a surface of a polishing layer 101 of the polishing unit 10a.

The polished material 40 is held by the holding unit 20 such that a surface to be polished is in contact with the polishing unit 10a and the polished material 40 is sandwiched between the polishing unit 10a and the holding unit 20. Rotating the polishing unit 10a and the holding unit 20 while keeping this state enables the polishing unit 10a to polish the polished material 40.

The polishing device 1 can be used to polish an optical material, a semiconductor device, and a substrate for hard disk, for example. Particularly, the polishing device 1 can be suitably used to polish a device including a semiconductor wafer having an oxide layer, a metal layer, and/or the like formed thereon.

### Polishing Unit

FIG. 2 is a cross-sectional view illustrating a configuration of the polishing unit 10a in accordance with Embodiment 1. As shown in FIG. 2, the polishing unit 10a includes a polishing pad 100a and a surface plate 150. The polishing pad 100a includes a polishing layer 101, a first adhesive layer 102, a base material layer 103, and a second adhesive layer 104 which are laminated in this order. The polishing pad 100a is bonded to the surface plate 150 via the second adhesive layer 104.

As shown in FIG. 2, the base material layer 103 has a diameter smaller than a diameter of the polishing layer 101. When seen in plan view from the side of the surface plate 150, the base material layer 103 is disposed inward of the polishing layer 101. This configuration can reduce an amount of the polishing slurry reaching a side surface of the base material layer 103 during polishing, as compared to a configuration in which the diameters of the polishing layer and the base material layer are equal to each other. Thus, even if the base material layer 103 has not been subjected to a water-repellent treatment, this configuration can reduce penetration of the polishing slurry into the base material layer 103. The reduction of penetration of the polishing slurry into the base material layer 103 can maintain adhesion between the base material layer 103 and the first adhesive layer 102 and adhesion between the base material layer 103 and the second adhesive layer 104. From the viewpoint of prevention of penetration of the polishing slurry into the base material layer 103, a difference in diameter between the base material layer 103 and the polishing layer 101 is preferably not less than 1 mm, more preferably not less than 1.5 mm, even more preferably not less than 2 mm. Meanwhile, from the viewpoint of hardly causing separation of the polishing layer 101 from the base material layer 103, the difference is preferably not more than 10 mm, more preferably not more than 7.5 mm, even more preferably not more than 5 mm.

In Embodiment 1, the polishing layer 101 and the base material layer 103 are laminated concentrically. This configuration can make a distance from an edge of the polishing layer 101 to the base material layer 103 constant, thereby making it possible to uniformly prevent the polishing slurry from reaching the base material layer 103.

The diameter of the base material layer 103 is greater than a diameter of the surface plate 150. This configuration is employed in order to solve a problem that may be caused in bonding of the polishing pad 100a to the surface plate 150. Specifically, with this configuration, it is possible to prevent misalignment between the surface plate 150 and the polishing pad 100a that may occur in bonding of the polishing pad 100a to the surface plate 150. From the viewpoint of prevention of misalignment between the surface plate 150 and the polishing pad 100a that may occur in the bonding, a difference in diameter between the base material layer 103 and the surface plate 150 is preferably not less than 1 mm, more preferably not less than 2 mm, even more preferably not less than 3 mm. Meanwhile, from the viewpoint of hardly causing separation of the polishing pad 100a from the surface plate 150, the difference is preferably not more than 20 mm, more preferably not more than 17 mm, even more preferably not more than 13 mm.

When seen in plan view from the side of the surface plate 150, the surface plate 150 is disposed inward of the base material layer 103. This configuration can make it difficult to cause separation of the polishing pad 100a from the surface plate 150. When seen in plan view from the side of the surface plate 150, the surface plate 150 and the base material layer 103 are arranged concentrically. However, the present invention is not limited to this. Alternatively, when seen in plan view from the side of the surface plate 150, the center of the surface plate 150 and the center of the base material layer 103 may be shifted from each other, provided that the surface plate 150 is disposed inward of the base material layer 103.

### Polishing Pad

The polishing pad 100a can be used in a similar manner to that for conventional polishing pads. For example, the polished material 40 can be polished by rotating the polishing pad 100a with the polishing layer 101 pressed onto the polished material 40 or by rotating the polished material 40 with the polished material 40 pressed onto the polishing layer 101.

### Polishing Layer

The polishing layer 101 is a layer for polishing the polished material 40. In the polishing unit 10a, the polishing layer 101 is positioned at a location where the polished material 101 comes in direct contact with the polished material 40. The polishing surface 101a, which is a surface of the polishing layer 101, may have a hole or a groove that facilitates accumulation of the polishing slurry or a groove that facilitates discharging of the polishing slurry.

The polishing layer 101 may be made of any material, provided that the material enables polishing of the polished material 40. The material of the polishing layer 101 may be selected as appropriate in accordance with the kind of the polished material 40. For example, from the viewpoint of favorably polishing, e.g., an optical material, a semiconductor device, and a substrate for hard disk, the material of the polishing layer 101 is preferably a foamed polyurethane resin.

The diameter of the polishing layer 101 can be selected as appropriate in accordance with the size of the polished material 40, which is to be polished. For example, the diameter of the polishing layer 101 can be not less than 700 mm or not less than 750 mm and not more than 850 mm or not more than 800 mm.

A thickness of the polishing layer 101 can be selected as appropriate in accordance with the material of the polished material 40, which is to be polished, the service life required in a polishing process, and the like. For example, the thickness of the polishing layer 101 can be not less than 1.0 mm or not less than 1.2 mm and not more than 3.0 mm or not more than 2.0 mm.

### Base Material Layer

The base material layer 103 is formed of a nonwoven fabric. The nonwoven fabric used in Embodiment 1 is not limited to any particular one, and can be selected from various known ones. Examples of the nonwoven fabric encompass polyolefin nonwoven fabrics, polyamide nonwoven fabrics, and polyester nonwoven fabrics. There is no particular limitation on a method for interlacing fibers to obtain the nonwoven fabric. For example, a needle punch method or hydroentangling method may be employed. As the nonwoven fabric, one kind selected from the above-indicated examples can be used alone or two or more kinds selected from the above-indicated examples can be used in combination. The nonwoven fabric originally has many gaps between fabrics and thus has high absorbency. However, when the nonwoven fabric is impregnated with a resin, the gaps are filled with the resin and accordingly the absorbency is reduced.

The base material layer 103 is preferably made of an impregnated nonwoven fabric obtained by impregnating a nonwoven fabric with a resin. Preferable examples of the resin encompass: polyurethane-based resins such as polyurethane and polyurethane urea; acryl-based resins such as polyacrylate and polyacrylonitrile; vinyl-based resins such as polyvinyl chloride, polyvinyl acetate, and polyvinylidene difluoride; polysulfone-based resins such as polysulfone and polyether sulfone; acylated cellulose-based resins such as acetylated cellulose and butyrylated cellulose; polyamide-based resins; and polystyrene-based resins. In a state before impregnation with the resin (in a web state), a density of the nonwoven fabric is preferably not more than 0.3 g/cm³, more preferably 0.1 g/cm³ to 0.2 g/cm³. A density of the nonwoven fabric after impregnation with the resin is preferably not more than 0.7 g/cm³, more preferably 0.3 g/cm³ to 0.5 g/cm³. Setting the densities of the nonwoven fabric before and after impregnation with the resin so as to be not more than the above-indicated upper limits improves the processing accuracy. Meanwhile, setting the densities of the nonwoven fabric before and after impregnation with the resin so as to be not less than the above-indicated lower limits can reduce penetration of the polishing slurry into the base material layer 103. A rate of adhesion of the resin to the nonwoven fabric is expressed by a weight of the adhered resin with respect to a weight of the nonwoven fabric, and is preferably not less than 50 wt%, more preferably 75 wt% to 200 wt%. Setting the rate of adhesion of the resin to the nonwoven fabric so as to be not more than the above-indicated upper limit can give the base material layer a desired cushioning property. Meanwhile, setting the rate of adhesion of the resin to the nonwoven fabric so as to be not less than the above-indicated lower limit can reduce penetration of the polishing slurry into the base material layer 103.

The diameter of the base material layer 103 may be set in accordance with the diameter of the polishing layer 101 so that the difference in diameter between the base material layer 103 and the polishing layer 101 falls within the above-indicated range.

A thickness of the base material layer 103 can be selected as appropriate in accordance with the material of the polished material 40, which is to be polished, the polishing performance required in a polishing process, and the like. For example, the thickness of the base material layer 103 can be not less than 0.5 mm or not less than 1.0 mm and not more than 2.0 mm or not more than 1.5 mm.

### Adhesive Layer

The first adhesive layer 102 is a layer for bonding the polishing layer 101 and the base material layer 103 to each other. The second adhesive layer 104 is a layer for bonding the polishing pad 100a and the surface plate 150 to each other. The first adhesive layer 102 and the second adhesive layer 104 may be either identical to each other or different from each other. Each of the first adhesive layer 102 and the second adhesive layer 104 may be (i) a double-sided adhesive tape made of a base material whose both surfaces have an adhesive agent applied thereto or (ii) an adhesive agent layer made of an adhesive agent alone.

Examples of the base material of the double-sided adhesive tape encompass: a polyimide-based resin; a polyester-based resin; a polyurethane-based resin; a polyethylene-based resin (e.g., polyethylene terephthalate (PET)); a polypropylene-based resin; a cellulose-based resin; a polyvinyl chloride-based resin; a polyvinyliden chloride-based resin; a polyvinyl alcohol-based resin; an ethylene-vinyl acetate copolymer-based resin; a polystyrene-based resin; a polycarbonate-based resin; an acrylic-based resin; and a laminate resin made of two or more kinds of them.

An adhesive agent on a side of the double-sided adhesive tape (used as the first adhesive layer 102) which side is adjacent to the polishing layer 101 or an adhesive agent of the adhesive agent layer (used as the first adhesive layer 102) is preferably a hot-melt adhesive. Another adhesive agent may be a hot-melt adhesive or another type of adhesive agent (e.g., a pressure-sensitive adhesive). Specific examples of another adhesive agent encompass: an adhesive agent on a surface of the double-sided adhesive tape (used as the first adhesive layer 102) which surface is adjacent to the base material layer 103; an adhesive agent on a surface of the double-sided adhesive tape (used as the second adhesive layer 104) which surface is adjacent to the base material layer 103; an adhesive agent on a surface of the double-sided adhesive tape (used as the second adhesive layer 104) which surface is adjacent to the surface plate 150; and an adhesive agent of the adhesive agent layer (used as the second adhesive layer 104).

The hot-melt adhesive includes a thermoplastic resin. Examples of the thermoplastic resin encompass an acrylic-based resin, an ethylene-vinyl acetate-based resin, an olefin-based resin, a synthetic rubber-based resin, a polyamide-based resin, and a polyester-based resin. Examples of another type of adhesive agent encompass a rubber-based adhesive agent, a silicone-based adhesive agent, a urethane-based adhesive agent, an epoxy-based adhesive agent, and a styrene-diene block copolymer-based adhesive agent. An element of the adhesive agent is not limited to a single element. Alternatively, the adhesive agent may be a mixed type containing two or more elements.

There is no limitation on a diameter of the first adhesive layer 102, provided that the first adhesive layer 102 having that diameter enables bonding of the polishing layer 101 to the base material layer 103. For example, the diameter of the first adhesive layer 102 is not less than the diameter of the base material layer 103 and not more than the diameter of the polishing layer 101. There is no limitation on a diameter of the second adhesive layer 104, provided that the second adhesive layer 104 having that diameter enables bonding of the base material layer 103 to the surface plate 150. For example, the diameter of the second adhesive layer 104 is not less than the diameter of the surface plate and not more than the diameter of the base material layer 103.

A thicknesses of each of the first adhesive layer 102 and the second adhesive layer 104 can be, for example, not less than 0.01 mm or not less than 0.02 mm and not more than 0.5 mm or not more than 0.2 mm.

### Surface Plate

The surface plate 150 is a member, included in the polishing device, for supporting the polishing pad 100a. The diameter of the surface plate 150 may be set in accordance with the diameter of the base material layer 103 so that the difference in diameter between the base material layer 103 and the surface plate 150 falls within the above-indicated range.

### Method for Manufacturing Polishing Pad 100a

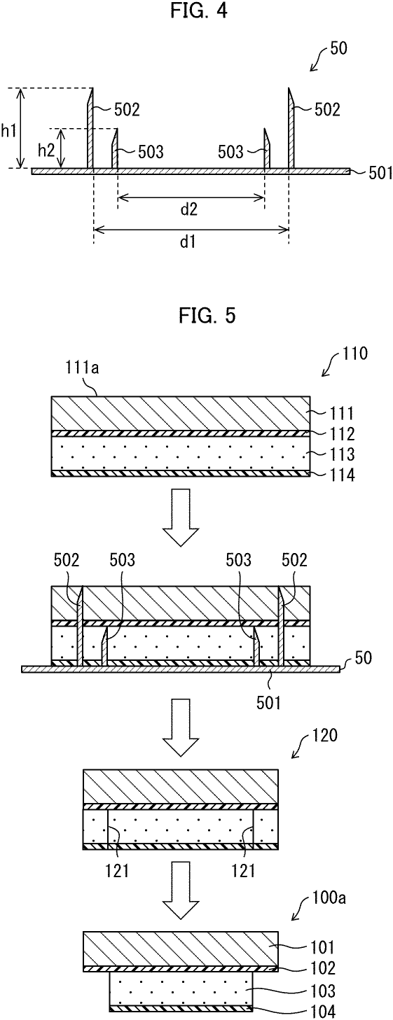

As described above, the polishing pad 100a in accordance with Embodiment 1 is configured such that the diameter of the base material layer 103 is smaller than the diameter of the polishing layer 101. Such a polishing pad 100a can be manufactured favorably with use of the later-described unique cutting die. The following description will discuss, with reference to FIGS. 3 to 5, a method for manufacturing the polishing pad 100a. FIG. 3 is a top view of a cutting die 50 used in a method for manufacturing the polishing pad 100a in accordance with Embodiment 1. FIG. 4 is a cross-sectional view taken along a broken line A-A′ in FIG. 3. FIG. 5 is a view schematically illustrating each step in the method for manufacturing the polishing pad 100a in accordance with Embodiment 1. The method for manufacturing the polishing pad 100a in accordance with Embodiment 1 includes a laminating step, a cutting step, and a removing step.

### Laminating Step

In the laminating step, a laminate pad 110 including a polishing sheet 111, a first adhesive sheet 112, a base material sheet 113, and a second adhesive sheet 114 which are laminated in this order is obtained (the first line in FIG. 5). There is no particular limitation on the laminating method, provided that the laminate pad 110 including these sheets laminated in the above-described order can be obtained. For example, these sheets may be sequentially laminated. For another example, a sheet constituted by the polishing sheet 111 and the first adhesive sheet 112 laminated to each other may be stacked on a sheet constituted by the base material sheet 113 and the second adhesive sheet 114 laminated to each other. A size of a plane surface of the laminate pad 110 may be selected as appropriate in accordance with the shape and size of the plane surface of a desired polishing layer 101. For example, the shape of the plane surface of the laminate pad 110 is a polygon (e.g., a quadrangle), a circle, or an ellipse. For example, in a case where the laminate pad 110 has a square shape, a length of each side of the laminate pad 110 may be not less than a diameter of a desired polishing layer 101. Note that a separation sheet may be further laminated on a surface of the second adhesive sheet 114 opposite to a surface of the second adhesive sheet 114 bonded to the base material sheet 113. A method for manufacturing each sheet will be described later.

### Cutting Step

In the cutting step, the cutting die 50 is used to cut the laminate pad 110 and to make a slit 121 in the base material sheet 113 and the second adhesive sheet 114, so as to obtain a slit pad 120 (the second and third lines in FIG. 5).

First of all, the following description will discuss the cutting die 50 with reference to FIGS. 3 and 4. As shown in FIGS. 3 and 4, the cutting die 50 includes a substrate 501, a cutting blade 502 provided on the substrate 501, a first slitting blade 503 (slitting blade) provided on the substrate 501, and two second slitting blades 504 provided on the substrate 501. The cutting blade 502 is a blade for cutting the laminate pad 110 into the shape of the polishing layer 101. The first slitting blade 503 is a blade for forming the base material sheet 113 into the shape of the base material layer 103.

The cutting blade 502 is designed to have a height h1, measured from the substrate 501, which is not less than a thickness of the laminate pad 110. When seen in plan view from the edge of the cutting blade 502, the first slitting blade 503 is disposed inside the cutting blade 502. The first slitting blade 503 is designed to have a height h2, measured from the substrate 501, which is not less than a sum of a thickness of the base material sheet 113 and a thickness of the second adhesive sheet 114. A difference h1-h2 between the height h1 of the cutting blade 502 and the height h2 of the first slitting blade 503 is designed to be identical to a thickness of the polishing sheet 111 or to a sum of the thickness of the polishing sheet 111 and a thickness of the first adhesive sheet. When seen in plan view from the edge of the cutting blade 502, each of the cutting blade 502 and the first slitting blade 503 has a circular shape. To be more specific, the cutting blade 502 and the first slitting blade 503 are arranged concentrically. That is, the first slitting blade 503 is disposed so as to be away from the cutting blade 502 by a constant distance. A height, measured from the substrate 501, of each second slitting blade 504 is equal to the height h2 of the first slitting blade 503. The second slitting blades 504 are disposed so as to extend between the cutting blade 502 and the first slitting blade 503.

A diameter d1 of the inner periphery of the cutting blade 502 may be set to be equal to the diameter of a desired polishing layer 101, and a diameter d2 of the inner periphery of the first slitting blade 503 may be set to be equal to the diameter of a desired base material layer 103.

In the cutting step, the cutting die 50 is inserted into the laminate pad 110 from the side of the second adhesive sheet 114. The height of the cutting blade 502 is designed to be not less than the overall height of the laminate pad 110. Thus, the whole of the laminate pad 110 can be cut by the cutting blade 502. Meanwhile, the difference h1-h2 between the height h1 of the first slitting blade 503 and the height h2 of the cutting blade 502 is designed to be equal to the thickness of the polishing sheet 111 or to the sum of the thickness of the polishing sheet 111 and the thickness of the first adhesive sheet 112. Thus, by the first slitting blade 503, a slit is made only in the base material sheet 113 and the second adhesive sheet 114 in the laminate pad 110. In this manner, the laminate pad 110 is cut into the shape of the polishing layer 101, so that the slit pad 120 having the slit 121 corresponding to the shape of the base material layer 103 can be obtained. Note that, in the configuration shown in FIG. 5, the height h1 of the cutting blade 502 is equal to the overall thickness of the laminate pad 110 and the height h2 of the first slitting blade 503 is equal to the sum of the thickness of the base material sheet 113 and the thickness of the second adhesive sheet 114 (i.e., the difference h1-h2 between the height h1 of the cutting blade 502 and the height h2 of the first slitting blade 503 is equal to the sum of the thickness of the polishing sheet 111 and the thickness of the first adhesive sheet 112). In a case where the height h1 of the cutting blade 502 is designed to be greater than the overall thickness of the laminate pad 110, the laminate pad 110 is placed stationary on a worktable in a state where the polishing surface 111a, which is a surface of the laminate pad 110, faces downward. Then, the cutting die 50 is inserted into the laminate pad 110 from the side of the second adhesive sheet 114 until the edge of the cutting blade 502 comes into contact with the worktable. Consequently, similarly to FIG. 5, the whole of the laminate pad 110 can be cut and the slit 121 can be made only in the base material sheet 113 and the second adhesive sheet 114 (not illustrated).

Since the cutting die 50 has not only the first slitting blade 503 but also the second slitting blades 504, it is possible to make not only the slit 121 but also two additional slits extending outward from the slit 121 (not illustrated). This can facilitate, in the later-described removing step, removal of portions of the base material sheet and the second adhesive sheet which portions are outward of the slit 121.

Use of the cutting die 50 configured as above makes it easier to manufacture the polishing pad including the layers arranged concentrically, as compared to the method that individually cuts the polishing layer 101 and the base material layer 103 and then stacks the cut pieces of the layers.

Note that, in a case of cutting the laminate pad further including the separation sheet laminated on the surface of the second adhesive sheet 114 opposite to the surface of the second adhesive sheet 114 bonded to the base material sheet 113, the height h2 of the first slitting blade 503 is set also in consideration of a thickness of the separation sheet. Specifically, the height h2 of the first slitting blade 503 is designed so as to be not less than a sum of the thickness of the base material sheet 113, the thickness of the second adhesive sheet 114, and the separation sheet. In the cutting step, the laminate pad is cut by the cutting blade, and slits are made in the base material sheet 113, the second adhesive sheet 114, and the separation sheet by the first slitting blade and the second slitting blade. Consequently, a slit pad can be obtained.

### Removing Step

In the removing step, the portions of the base material sheet and the second adhesive sheet in the slit pad 120 which portions are outward of the slit 121 are removed so as to obtain a polishing pad 100a (the fourth line in FIG. 5). There is no particular limitation on a method for the removal. For example, unnecessary areas of the base material sheet and the second adhesive sheet may be removed by a hand along the slits made by the first slitting blade 503 and the second slitting blades 504.

In the case where the laminate pad including the separation sheet laminated therewith has been cut, portions of the base material sheet, the second adhesive sheet, and the separation sheet in the slit pad which portions are outward of the slit may be removed in the removing step. In this manner, the polishing pad including the polishing layer 101, the first adhesive layer 102, the base material layer 103, the second adhesive layer 104, and the separation layer which are laminated in this order can be obtained.

Note that, in a case of using the polishing pad including the separation layer, the separation layer may be removed and then the polishing pad from which the separation layer has been removed may be bonded to the surface plate.

### Method for Manufacturing Each Sheet

### Polishing Sheet

The polishing sheet 111 can be produced by a production method such as generally-known molding or slab molding. First, a polyurethane block is formed by any of these production methods, and the block is subjected to, e.g., slicing so as to be formed into a sheet. In this manner, a polishing sheet 111 made of a polyurethane resin is formed. The description in the section “(Polishing layer)” is applied to a shape of a polishing surface 111a, which is a surface of the polishing sheet 111, and a thickness of the polishing surface 111.

The polishing sheet 111 can be formed by preparing a polyurethane resin curable composition containing a polyisocyanate compound and a polyol compound and then curing the polyurethane resin curable composition.

The polishing sheet 111 is made of a foamed polyurethane resin. Foaming can be carried out by dispersing, in a polyurethane resin, a blowing agent containing hollow fine particles. In this case, the polishing sheet can be formed by preparing a polyurethane resin foaming curable composition containing a polyisocyanate compound, a polyol compound, and a blowing agent and then foaming-curing the polyurethane resin foaming curable composition.

The polyurethane resin curable composition can be, for example, a two-pack composition that is to be prepared by mixing a liquid A containing a polyisocyanate compound and a liquid B containing the other component(s). The liquid B, which contains the other component(s), can be a composition obtained by mixing three or more kinds of liquids into which the components are separated.

The polyisocyanate compound may contain a prepolymer prepared by a reaction of a polyisocyanate compound and a polyol compound, such as the one often used in this technical field. Usable as the prepolymer in the present invention is any of prepolymers containing an unreacted isocyanate group generally used in this field.

### Isocyanate Component

Examples of the isocyanate component encompass m-phenylenediisocyanate, p-phenylenediisocyanate, 2,6-tolylene diisocyanate (2,6-TDI), 2,4-tolylene diisocyanate (2,4-TDI), naphthalene-1,4-diisocyanate, diphenylmethane-4,4′-diisocyanate (MDI), 4,4′-methylene-bis(cyclohexyl isocyanate) (hydrogenated MDI), 3,3′-dimethoxy-4,4′-biphenyldiisocyanate, 3,3′-dimethyldiphenylmethane-4,4′-diisocyanate, xylylene-1,4-diisocyanate, 4,4′-diphenylpropanediisocyanate, trimethylenediisocyanate, hexamethylenediisocyanate, propylene-1,2-diisocyanate, butylene-1,2-diisocyanate, cyclohexylene-1,2-diisocyanate, cyclohexylene-1,4-diisocyanate, p-phenylenediisothiocyanate, xylylene-1,4-diisothiocyanate, and ethylidynediisothiocyanate.

### Polyol Component

Examples of the polyol component encompass: diol such as ethylene glycol, diethylene glycol, triethylene glycol, 1,2-propanediol, 1,3-propanediol, 1,3-butanediol, 1,4-butanediol, neopentylglycol, pentanediol, 3-methyl-1,5-pentanediol, and 1,6-hexanediol; polyether polyol such as polytetramethylene glycol (PTMG), polyethylene glycol, polypropylene glycol; polyester polyol such as a product of reacting ethylene glycol and an adipic acid and a product of reacting butylene glycol and an adipic acid; a polycarbonate polyol; and polycaprolactone polyol.

### Curing Agent

A curing agent can be a polyamine-based curing agent. Polyamine may be, for example, diamine, examples of which encompass: alkylenediamines such as ethylenediamine, propylenediamine, and hexamethylenediamine; diamines having an aliphatic ring such as isophoronediamine and dicyclohexylmethane-4,4′-diamine; diamines having an aromatic ring such as 3,3′-dichloro-4,4′-diaminodiphenyl methane (also called methylenebis-o-chloroaniline); and diamines having a hydroxyl group such as 2-hydroxyethylethylenediamine, 2-hydroxyethylpropylenediamine, di-2-hydroxyethylethylenediamine, di-2-hydroxyethylpropylenediamine, 2-hydroxypropylethylenediamine, and di-2-hydroxypropylethylenediamine, particularly, hydroxyalkylalkylenediamine. Alternatively, a 3-functional triamine compound or a 4 or more-functional polyamine compound can be used.

The curing agent may be another type of curing agent other than the polyamine-based curing agent. Examples of another type of curing agent encompass: low molecular weight diols such as ethylene glycol, diethylene glycol, triethylene glycol, 1,2-propanediol, 1,3-propanediol, 1,3-butanediol, 1,4-butanediol, neopentylglycol, pentanediol, 3-methyl-1,5-pentanediol, and 1,6-hexanediol; and polyol curing agents such as high molecular weight polyol compounds, e.g., poly(oxytetramethylene)glycol, polyethylene glycol, and polypropylene glycol.

### Use Amount of Curing Agent

Physical properties of the polishing sheet 111 can be adjusted also by a chemical structure and a use amount of the curing agent. The amount of the curing agent is set so that an amount of an active hydrogen group (an amino group or a hydroxyl group) existing in the curing agent is preferably 0.60 to 1.40, more preferably 0.70 to 1.20, even more preferably 0.80 to 1.10 in equivalent ratio with respect to an isocyanate group existing at a terminal of the prepolymer.

### Gas Babbles

The polishing sheet 111 may have gas babbles and/or the like in order to improve the polishing performance. The gas babbles can be formed by utilizing, e.g., foaming caused with use of hollow fine particles, chemical foaming, or mechanical foaming. The “hollow fine particles” mean microspheres having a void, and encompass the ones having a spherical shape, an ellipse shape, and shapes similar to the spherical shape or ellipse shape. The hollow fine particles may be, for example, the one obtained by heating and expanding non-foamed, thermally expandable microspheres constituted by an outer shell (polymer shell) made of a thermoplastic resin and a low-boiling hydrocarbon encapsulated in the outer shell. The polymer shell may be, for example, a thermoplastic resin such as an acrylonitrilevinylidene chloride copolymer, an acrylonitrile-methyl methacrylate copolymer, or a vinyl chloride-ethylene copolymer, as disclosed in Japanese Patent Application Publication, Tokukaisho, No. 57-137323 and the like. Similarly, the low-boiling hydrocarbon encapsulated in the polymer shell may be, for example, isobutane, pentane, isopentane, or petroleum ether.

### Base Material Sheet

The base material sheet 113 can be manufactured by impregnating a nonwoven fabric with a resin. The description in the section “(Base material layer)” is applied to the kind of the nonwoven fabric, the kind of the resin, the densities of the nonwoven fabric before and after impregnation with the resin, the rate of adhesion of the resin to the nonwoven fabric, and the thickness of the base material sheet 113.

### Adhesive Sheet

The description in the section “(Adhesive layer)” is applied to the materials and thicknesses of the first adhesive sheet 112 and second adhesive sheet 114.

### Method for Manufacturing Polishing Unit

As described above, the polishing unit 10a in accordance with Embodiment 1 is configured such that the diameter of the base material layer 103 is smaller than the diameter of the polishing layer 101 and is greater than the diameter of the surface plate 150. The polishing unit 10a configured as above can be manufactured by bonding, to the surface plate 150 having a diameter smaller than the diameter of the base material layer 103, the polishing pad 100a manufactured by the method for manufacturing the above-described polishing pad. In the method for manufacturing the polishing unit 10a, the polishing pad 100a may be bonded to the surface plate 150 via the second adhesive layer such that the surface plate 150 is disposed inward of the base material layer 103 when seen in plan view from the side of the surface plate 150.

### Embodiment 2

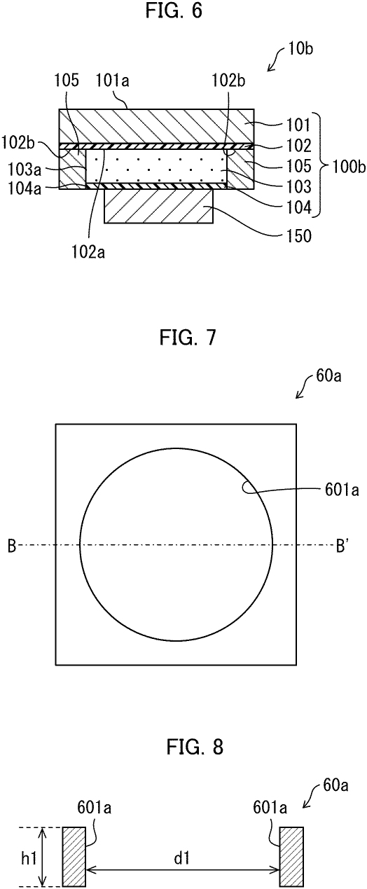

The following will give a description of another embodiment of the present invention with reference to FIG. 6. Note that, for convenience, members having identical functions to those of the above embodiment are given identical reference signs, and their descriptions will be omitted.

FIG. 6 is a cross-sectional view illustrating a configuration of a polishing unit 10b in accordance with Embodiment 2. As shown in FIG. 6, the polishing unit 10b includes a polishing pad 100b and a surface plate 150. The polishing pad 100b further includes, in addition to the configuration of the polishing pad 100a in accordance with Embodiment 1, a frame 105 having a ring shape.

As shown in FIG. 6, the polishing pad 100b in accordance with Embodiment 2 includes a polishing layer 101 and a base material layer 103 having a diameter smaller than a diameter of the polishing layer 101. The polishing layer 101 and the base material layer 103 are bonded to each other via a first adhesive layer 102. The base material layer 103 has a surface which is opposite to the polishing layer 101 and which is provided with a second adhesive layer 104. The base material layer 103 has an outer peripheral side surface 103a provided with the frame 105 having a ring shape.

As shown in FIG. 6, the base material layer 103 has a diameter smaller than a diameter of the polishing layer 101, and the base material layer 103 is disposed inward of the polishing layer 101. In a case of a polishing pad in which an outer peripheral side surface of a base material layer is not covered with a frame, setting a diameter of the base material layer so as to be smaller than a diameter of a polishing layer can reduce an amount of a polishing slurry reaching the outer peripheral side surface of the base material layer during polishing, as compared to a case where the diameters of the polishing layer and the base material layer are set so as to be equal to each other. In the polishing pad 100b in accordance with Embodiment 2, the diameter of the base material layer 103 is smaller than the diameter of the polishing layer 101 and the frame 105 covers the outer peripheral side surface 103a of the base material layer 103. Thus, the amount of the polishing slurry reaching the outer peripheral side surface 103a of the base material layer 103 during polishing is further reduced.

In Embodiment 2, the polishing layer 101 and the base material layer 103 are laminated concentrically. This configuration makes a distance from an edge of the polishing layer 101 to the base material layer 103 constant. This can uniformly prevent the polishing slurry from reaching the base material layer 103.

### Frame Having a Ring Shape

Furthermore, in Embodiment 2, the frame 105 surrounds the outer peripheral side surface 103a of the base material layer 103 and an outer peripheral side surface 104a of the second adhesive layer 104. As a result, the frame 105 covers (i) the outer peripheral side surface 103a of the base material layer 103, (ii) the outer peripheral side surface 104a of the second adhesive layer 104, and (iii) an area 102b of a surface 102a of the first adhesive layer 102 which surface 102a is adjacent to the base material layer 103, the area 102b being not in contact with the base material layer 103, i.e., the area 102b being exposed from the base material layer 103. Providing such a frame 105 can more reliably prevent the polishing slurry from reaching the base material layer 103, as compared to a case where the diameters of the polishing layer and the base material layer are equal to each other. As a result, it is possible to further reduce penetration of the polishing slurry into the base material layer 103. The reduction of penetration of the polishing slurry into the base material layer 103 can maintain adhesion between the base material layer 103 and the first adhesive layer 102 and adhesion between the base material layer 103 and the second adhesive layer 104. The covering is made so as not to form a gap between the frame 105 and the surface to be covered.

From the viewpoint of further reducing penetration of the polishing slurry into the base material layer 103, the frame 105 preferably does not have a void communicated with an outer peripheral side surface and an inner peripheral surface. In a case where the frame 105 is formed of a resin, the frame 105 is, for example, (i) an independently foamed resin molded body in which a gas babble formed in the resin is not communicated with the outer peripheral side surface or the inner peripheral surface or (ii) a non-foaming resin molded body. From the viewpoint of effectively utilizing the material of the polishing layer 101, the material of the frame 105 is preferably identical to the material of the polishing layer 101.

In a case where the diameter of the surface plate 150 is not more than the diameter of the base material layer 103, a polished material is typically polished in a center portion of the polishing surface 101a, and thus the polished material would not pass through an outer edge portion of the polishing surface 101a. Note that the center portion of the polishing surface 101a refers to an area of the polishing layer 101 overlapping an area of the surface plate 150 which area is inward of the outer periphery of the surface plate 150 when seen in plan view from the side of the polishing surface 101a. The outer edge portion of the polishing surface 101a refers to an area of the polishing surface 101a overlapping an area of the surface plate 150 which area is outward of the outer periphery of the surface plate 150 when seen in plan view from the side of the polishing surface 101a. In a case where the diameter of the surface plate 150 is not more than the diameter of the base material layer 103, the frame 105 is positioned at a location overlapping the outer edge portion of the polishing surface 101a when seen in plan view from the side of the polishing surface 101a. As described above, since the polished material does not pass through the outer edge portion of the polishing surface 101a, it is not necessary to consider the cushioning property of the frame 105. A height of the frame 105 only needs to be not less than the sum of a thickness of the base material layer 103 and a thickness of the second adhesive layer 104. By setting the height of the frame 105 so as to be greater than the sum of the thickness of the base material layer 103 and the thickness of the second adhesive layer 104, the frame 105 can function as a guide in bonding of the polishing pad 100b to the surface plate 150, thereby more reliably preventing misalignment that may occur in the bonding. In Embodiment 2, the height of the frame 105 is equal to the sum of the thickness of the base material layer 103 and the thickness of the second adhesive layer 104.

An inner diameter of the frame 105 is equal to the diameter of the base material layer 103. The description of the preferable diameter of the base material layer 103 made in the section “(Base material layer)” is applied to a preferable inner diameter of the frame 105.

An outer diameter of the frame 105 is preferably greater than the diameter of the surface plate 150 and not greater than the diameter of the polishing layer 101. In Embodiment 2, the outer diameter of the frame 105 is equal to the diameter of the polishing layer 101.

### Method for Manufacturing Polishing Pad 100b

As described above, the polishing pad 100b in accordance with Embodiment 2 is configured such that the frame 105 covers the outer peripheral side surface of the base material layer 103. Such a polishing pad 100b can be manufactured favorably with use of the later-described die. The following description will discuss, with reference to FIGS. 7 to 9, a method for manufacturing the polishing pad 100b.

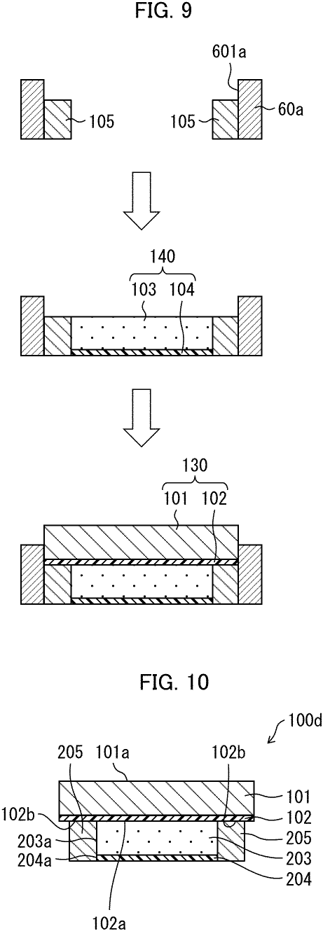

FIG. 7 is a top view of a die 60a used in a method for manufacturing the polishing pad 100b in accordance with Embodiment 2. FIG. 8 is a cross-sectional view taken along a dot-and-dash line B-B′ in FIG. 7. FIG. 9 is a view schematically illustrating a bonding step in the method for manufacturing the polishing pad 100b in accordance with Embodiment 2. The method for manufacturing the polishing pad 100b in accordance with Embodiment 2 includes an upper layer production step, a lower layer production step, a frame preparation step, and a bonding step.

### Upper Layer Production Step

In the upper layer production step, an upper sheet constituted by a polishing sheet and a first adhesive sheet laminated to each other is cut into the shape of the polishing layer 101, so that an upper layer 130 can be obtained. The upper sheet may be produced by, e.g., laminating the polishing sheet and the first adhesive sheet by a roll-to-roll process. A width and a length of the upper sheet constituted by the polishing sheet and the first adhesive sheet laminated to each other only need to be not less than a desired diameter of the polishing layer 101. In the upper layer production step, the cutting die having the desired shape of the polishing layer 101 may be used to cut the upper sheet. A method for manufacturing each sheet will be described later.

### Lower Layer Production Step

In the lower layer production step, a lower sheet constituted by a base material sheet containing a nonwoven fabric and a second adhesive sheet laminated to each other is cut into the shape of the base material layer 103, so that a lower layer can be obtained. The lower sheet may be produced by, e.g., laminating the base material sheet and the second adhesive sheet by a roll-to-roll process. A width and a length of the lower sheet constituted by the base material sheet and the second adhesive sheet laminated to each other only need to be not less than a desired diameter of the base material layer 103. In the lower layer production step, the cutting die having the desired shape of the base material layer 103 may be used to cut the lower sheet. A method for manufacturing each sheet will be described later.

### Frame Preparation Step

In the frame preparation step, the frame 105 which has a ring shape and which has an inner diameter equal to an outer diameter of the base material layer 103 is prepared. In the frame preparation step, a frame sheet is cut to obtain the frame 105 which has a ring shape and which has an inner diameter equal to the outer diameter of the base material layer 103. In the frame preparation step, if the thickness of the polishing sheet used in the upper layer production step is equal to the thickness of the lower sheet, the polishing sheet or the upper sheet may be used as the frame sheet. With this, the frame 105 and the polishing layer 101 can be made of the same material, and the material of the polishing layer 101 used in the upper layer production step can be effectively used. A method for manufacturing the frame sheet will be described later.

In the frame preparation step, the frame sheet may be cut into a desired ring shape to obtain the frame 105. In the frame preparation step, the frame sheet may be cut into a plurality of parts and the plurality of parts may be combined to obtain the frame 105. Alternatively, the frame sheet may be cut into a single frame 105 having a ring shape. In the case where the plurality of parts are combined to obtain the frame 105 having a ring shape, the frame sheet may be cut into the plurality of parts having such shapes whose ends are fitted to each other in a height direction of the parts (i.e., a thickness direction of the frame sheet) when the plurality of parts are combined. Forming the frame 105 having a ring shape by combining the plurality of parts having been cut into such shapes gives a favorable processing property. In the case where the thickness of the polishing sheet used in the upper layer production step is equal to the thickness of the lower sheet, a remaining part of the upper sheet after cutting the upper sheet into the upper layer 130 may be used as the frame sheet, and may be cut into the plurality of parts. In this manner, the remaining part can be effectively utilized.

### Bonding Step

In the bonding step, the lower layer 140 is fitted into the inside of the frame 105, and the frame 105 and the lower layer 140 are bonded to the upper layer 130 such that the base material layer 103 and the frame 105 are bonded to the first adhesive layer 102. Consequently, the polishing pad 100b can be obtained. In the bonding step, the frame 105 and the lower layer 140 are bonded to the upper layer 130 such that the polishing layer 101 is disposed inward of the base material layer 103 when seen in plan view from the side of the second adhesive layer 104 and the base material layer 103 and the frame 105 are bonded to the first adhesive layer 102. To be more specific, the frame 105 and the lower layer 140 are bonded to the upper layer 130 such that the base material layer 103 and the polishing layer 101 are arranged concentrically when seen in plan view from the side of the second adhesive layer 104 and the base material layer 103 and the frame 105 are bonded to the first adhesive layer 102.

The bonding step is preferably carried out with use of the die 60a shown in FIGS. 7 and 8. The die 60a has a hole 601a. A diameter d1 of the hole 601a is designed to be equal to the outer diameter of the frame 105 and a diameter of the upper layer 130. A height h1 of the hole 601a is designed so as to be not less than a thickness of the lower layer 140. In FIG. 8, the hole 601a is a through-hole. Alternatively, the hole 601a may be a bottomed hole.

An aspect of the bonding step will be described with reference to FIG. 9. First, the frame 105 is fitted into the hole 601a of the die 60a (the first line in FIG. 9). Next, with the second adhesive layer 104 positioned on a lower side, the lower layer 140 is fitted into the inside of the frame 105 (the second line in FIG. 9). Then, with the first adhesive layer 102 positioned on a lower side, the upper layer 130 is fitted into the hole 601a such that (i) the upper layer 130 comes into contact with upper surfaces of the frame 105 and the lower layer 140 thus fitted and (ii) the first adhesive layer 102 is bonded to the frame 105 and the base material layer 103 (the third line in FIG. 9). In this manner, it is possible to obtain the polishing pad 100b in which the layers and the frame 105 are arranged concentrically. Further, in a case where the outer diameter of the frame 105 is equal to the diameter of the polishing layer 101, use of the die 60a configured as above makes it possible to more easily manufacture the polishing pad in which the layers are arranged concentrically, as compared to a method for laminating the layers without use of the die. Note that, in order to sufficiently bond the polishing layer 101 and the base material layer 103 to each other, thermal pressing may be carried out after the polishing pad is taken out from the die 60a. A temperature, a pressure, and time may be set as appropriate in accordance with the kinds of the first adhesive layer 102 and the second adhesive layer 104.

Another aspect of the bonding step can be carried out with use of the same die 60a by fitting the members into the hole 601a in a different order. First, the upper layer 130 is fitted into the hole 601a of the die 60a. Next, the frame 105 is fitted into the hole 601a of the die 60a such that the frame 105 is bonded to the first adhesive layer 102 of the upper layer 130 thus fitted. Then, with the base material layer 103 positioned on a lower side, the lower layer 140 is fitted into the inside of the frame 105 thus fitted such that (i) the lower layer 140 comes into contact with the upper surface of the upper layer 130 and the inner peripheral surface of the frame 105 thus fitted and (ii) the first adhesive layer is bonded to the base material layer 103. Also in this manner, it is possible to obtain the polishing pad 100b in which the layers and the frame 105 are arranged concentrically.

### Sheets

The description in the section “Method for manufacturing each sheet” in Embodiment 1 is applied to methods for manufacturing the polishing sheet, the base material sheet, and the adhesive sheet, as well as the materials and thicknesses of the polishing sheet, the base material sheet, and the adhesive sheet. The description in the section “(Frame having a ring shape)” is applied to the material and thickness of the frame sheet.

### Embodiment 3

The following will give a description of another embodiment of the present invention. Note that, for convenience, members having identical functions to those of the above embodiments are given identical reference signs, and their descriptions will be omitted.

FIG. 10 is a cross-sectional view illustrating a configuration of a polishing pad 100d in accordance with Embodiment 3. As shown in FIG. 10, the polishing pad 100d includes a polishing layer 101, a first adhesive layer 102, a base material layer 203, a second adhesive layer 204, and a frame 205 having a ring shape. Diameters of the base material layer 203, the second adhesive layer 204, and the frame 205 are respectively smaller than the diameters of the base material layer 103, the second adhesive layer 104, and the frame 105 in the polishing pad 100b of Embodiment 2, and are greater than the diameter of the surface plate 150. An outer diameter of the frame 205 is smaller than a diameter of the polishing layer 101. The frame 205 covers (i) an outer peripheral side surface 203a of the base material layer 203, (ii) an outer peripheral side surface 204a of the second adhesive layer 204, and (iii) a portion of an area 102b of a surface 102a of the first adhesive layer 102 which surface 102a is adjacent to the base material layer 203, the portion being not in contact with the base material layer 203. Thus, it is possible to employ the configuration in which the outer diameter of the frame 205 is smaller than the diameter of the polishing layer 101, provided that the frame 205 covers at least the outer peripheral side surface 203a of the base material layer 203. With this configuration, an amount of a polishing slurry reaching the outer peripheral side surface 203a of the base material layer 203 during polishing is reduced, as compared to a case where the diameters of the polishing layer 101 and the base material layer 203 are equal to each other. Thus, it is possible to reduce penetration of the polishing slurry into the base material layer 203.

### Method for Manufacturing Polishing Pad 100d

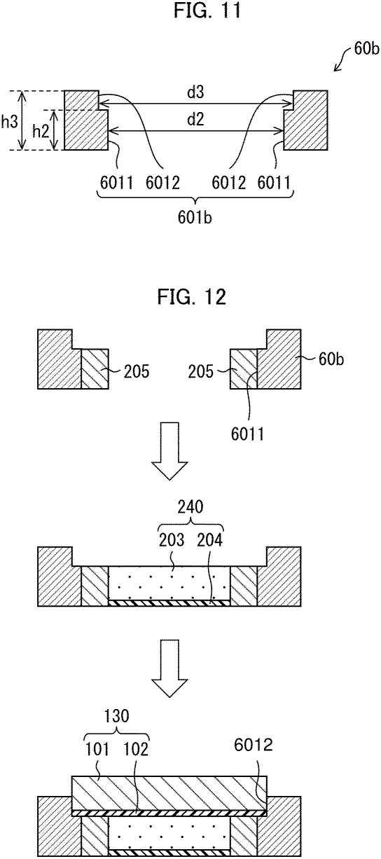

The following description will discuss, with reference to FIGS. 11 and 12, a method for manufacturing the polishing pad 100d in accordance with Embodiment 3. FIG. 11 is a cross-sectional view illustrating a die 60b used in a method for manufacturing the polishing pad 100d in accordance with Embodiment 3. FIG. 12 is a view schematically illustrating a bonding step in the method for manufacturing the polishing pad 100d in accordance with Embodiment 3. The upper layer production step, lower layer production step, and frame preparation step in the method for manufacturing the polishing pad 100d in accordance with Embodiment 3 are similar to those in the method for manufacturing the polishing pad 100b described above. The following will discuss differing points in the bonding step.

### Bonding Step

The bonding step is preferably carried out with use of the die 60b shown in FIG. 11. The die 60b has a hole 601b constituted by a first fitting part 6011 and a second fitting part 6012 arranged side by side in a height direction. A diameter d2 of the first fitting part 6011 is designed to be equal to the diameter of the frame 205. A height h2 of the first fitting part 6011 is designed to be not more than a thickness of the lower layer 240. A diameter d3 of the second fitting part 6012 is designed to be equal to the diameter of the upper layer 130. An overall height of the hole 601b (the sum of the height of the first fitting part 6011 and the height of the second fitting part 6012) h3 is designed to be not less than the thickness of the lower layer 240. When seen in plan view from an opening closer to the first fitting part 6011, the first fitting part 6011 and the second fitting part 6012 are arranged concentrically. In FIG. 11, the hole 601b is a through-hole. Alternatively, the hole 601b may be a bottomed hole whose bottom surface is provided on a side closer to the first fitting part 6011.

An aspect of the bonding step will be described with reference to FIG. 12. First, the frame 205 is fitted into the first fitting part 6011 of the hole 601b of the die 60b (the first line in FIG. 12). Next, with a second adhesive layer 204 positioned on a lower side, the lower layer 240 is fitted into the inside of the frame 205 (the second line in FIG. 12). Then, with a first adhesive layer 102 positioned on a lower side, the upper layer 130 is fitted into the second fitting part 6012 of the hole 601b such that (i) the upper layer 130 comes into contact with upper surfaces of the frame 205 and the lower layer 240 thus fitted and (ii) the first adhesive layer 102 is bonded to the frame 205 and the base material layer 203 (the third line in FIG. 12). In this manner, it is possible to obtain the polishing pad 100d in which the layers and the frame 205 are arranged concentrically. Further, in a case where the outer diameter of the frame 205 is smaller than the diameter of the polishing layer 101, use of the die 60b configured as above makes it possible to more easily manufacture the polishing pad in which the layers are arranged concentrically, as compared to a method for laminating the layers without use of the die.

### Embodiment 4

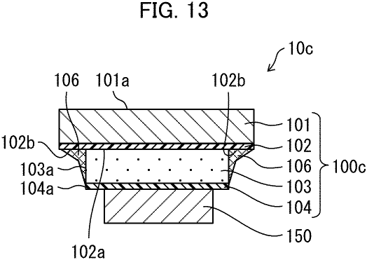

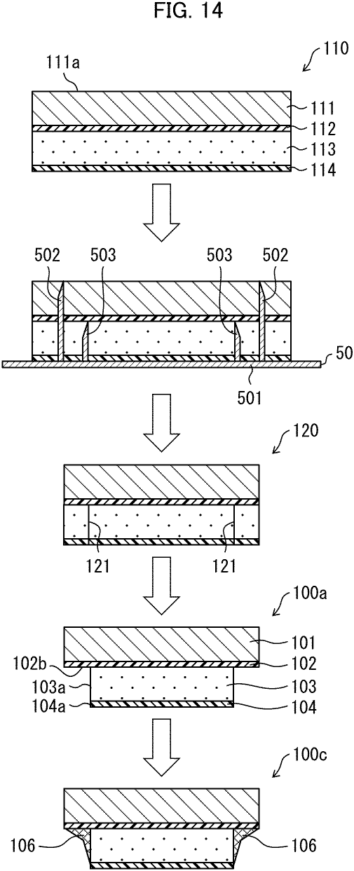

The following will give a description of another embodiment of the present invention with reference to FIG. 13. Note that, for convenience, members having identical functions to those of the above embodiments are given identical reference signs, and their descriptions will be omitted.

FIG. 13 is a cross-sectional view illustrating a configuration of a polishing unit 10c in accordance with Embodiment 4. As shown in FIG. 13, the polishing unit 10c includes a polishing pad 100c and a surface plate 150. Further, the polishing pad 100c includes, in addition to the configuration of the polishing pad 100a in accordance with Embodiment 1, a sealing part 106.

As shown in FIG. 13, the polishing pad 100c in accordance with Embodiment 4 includes a polishing layer 101 and a base material layer 103 having a diameter smaller than a diameter of the polishing layer 101. The polishing layer 101 and the base material layer 103 are bonded to each other via a first adhesive layer 102. A second adhesive layer 104 is provided on a surface of the base material layer 103 which surface is opposite to the polishing layer 101. In addition, the sealing part 106 is formed on an outer peripheral side surface 103a of the base material layer 103.

As shown in FIG. 13, the base material layer 103 has a diameter smaller than a diameter of the polishing layer 101, and the base material layer 103 is disposed inward of the polishing layer 101. In a case of a polishing pad in which an outer peripheral side surface of a base material layer is not covered with a sealing part, setting a diameter of the base material layer so as to be smaller than a diameter of a polishing layer can reduce an amount of a polishing slurry reaching the outer peripheral side surface of the base material layer during polishing, as compared to a case where the diameters of the polishing layer and the base material layer are equal to each other. In the polishing pad 100c in accordance with Embodiment 4, the diameter of the base material layer 103 is smaller than the diameter of the polishing layer 101, and, in addition, the sealing part 106 covers the outer peripheral side surface 103a of the base material layer 103. Thus, the amount of the polishing slurry reaching the outer peripheral side surface 103a of the base material layer 103 during polishing is further reduced.

### Sealing Part

The sealing part 106 is a protection member which is formed of a resin and which covers the outer peripheral side surface 103a of the base material layer 103 in order to prevent penetration of the slurry into the base material layer 103. As shown in FIG. 13, the sealing part 106 covers, in addition to the outer peripheral side surface 103a of the base material layer 103, (i) an area 102b of a surface 102a of the first adhesive layer 102 which surface 102a is adjacent to the base material layer 103, the area 102b being not in contact with the base material layer 103, i.e., the area 102b being exposed from the base material layer 103, and (ii) an outer peripheral side surface 104a of the second adhesive layer 104. This can prevent penetration of the slurry from a boundary between the first adhesive layer 102 and the base material layer 103 and a boundary between the second adhesive layer 104 and the base material layer 103. The reduction of penetration of the polishing slurry into the base material layer 103 can maintain adhesion between the base material layer 103 and the first adhesive layer 102 and adhesion between the base material layer 103 and the second adhesive layer 104. The covering is made so as not to form a gap between the frame 105 and the surface to be covered. In a case where the diameter of the surface plate 150 is not more than the diameter of the base material layer 103, a polished material is typically polished in a center portion of the polishing surface 101a, and thus the polished material would not pass through an outer edge portion of the polishing surface 101a. Note that the center portion of the polishing surface 101a refers to an area of the polishing layer 101 overlapping an area of the surface plate 150 which area is inward of the outer periphery of the surface plate 150 when seen in plan view from the side of the polishing surface 101a. The outer edge portion of the polishing surface 101a refers to an area of the polishing surface 101a overlapping an area of the surface plate 150 which area is outward of the outer periphery of the surface plate 150 when seen in plan view from the side of the polishing surface 101a. In a case where the diameter of the surface plate 150 is not more than the diameter of the base material layer 103, the sealing part 106 is positioned at a location overlapping the outer edge portion of the polishing surface 101a when seen in plan view from the side of the polishing surface 101a. As described above, the polished material does not pass through the outer edge portion of the polishing surface 101a. Therefore, it is not necessary to consider the cushioning property of the sealing part 106.

When measured in a bending mode in a dynamic mechanical analysis at a frequency of 0.16 Hz, a loss modulus E″(S) at 40° C. of the sealing part 106 in accordance with Embodiment 4 is preferably not less than a loss modulus E″(P) at 40° C. of the polishing layer 101. The loss modulus E″(S) at 40° C. of the sealing part 106 is more preferably 1 to 10 times greater than the loss modulus E″(P) at 40° C. of the polishing layer 101, even more preferably 1.2 to 5 times greater than the loss modulus E″(P) at 40° C. of the polishing layer 101. That is, E″(S)/E″(P) is more preferably 1 to 10, even more preferably 1.2 to 5. To be more specific, the loss modulus E″(S) at 40° C. of the sealing part 106 is preferably 10 MPa to 1000 MPa, more preferably 12 MPa to 500 MPa.

When measured in the bending mode in the dynamic mechanical analysis at a frequency of 0.16 Hz, a storage modulus E′(S) at 40° C. of the sealing part 106 in accordance with Embodiment 4 is preferably substantially equal to a storage modulus E′(P) at 40° C. of the polishing layer 101. The storage modulus E′(S) at 40° C. of the sealing part 106 in accordance with Embodiment 4 is more preferably 0.1 to 10 times greater than the storage modulus E′(P) at 40° C. of the polishing layer 101, even more preferably 0.25 to 1 times greater than the storage modulus E′(P) at 40° C. of the polishing layer 101. That is, E′(S)/E′(P) is more preferably 0.1 to 10, even more preferably 0.25 to 1. To be more specific, the storage modulus E′(S) at 40° C. of the sealing part 106 is preferably 10 MPa to 5000 MPa, more preferably 25 MPa to 500 MPa.

When measured in the bending mode in the dynamic mechanical analysis at a frequency of 0.16 Hz, tanδ(S) at 40° C. of the sealing part 106 in accordance with Embodiment 4 is preferably not less than tanδ(P) at 40° C. of the polishing layer 101. Specifically, it is more preferable that tanδ(S)/tanδ(P) be 1 to 10, and it is even more preferable that tanδ(S)/tanδ(P) be 1.5 to 7. To be more specific, tanδ(S) at 40° C. of the sealing part 106 in accordance with Embodiment 4 is preferably 0.2 to 1.0, more preferably 0.3 to 0.7.

In a case where the measurement values of the sealing part 106 obtained by the measurement in the bending mode of the dynamic mechanical analysis are within the above range, i.e., the loss modulus E″(S) of the sealing part 106 is not less than the storage modulus E″(P) of the polishing layer 101 and the storage modulus E′(S) of the sealing part 106 is substantially equal to the storage modulus E′(P) of the polishing layer 101, it is possible to prevent the sealing part 106 from being cracked or broken by a force applied to the polishing pad 100c when the polishing pad 100c is bonded to the surface plate 150. As a result, it is possible to more reliably prevent the slurry from penetrating into the base material layer 103 through the sealing part 106.

Note that the loss modulus E″(S), the storage modulus E′(S), and tanδ(S) of the sealing part 106 obtained by the measurement in the bending mode in the dynamic mechanical analysis were achieved by measurement conducted on a test piece formed of the same material as that of the sealing part 106. The loss modulus E″(P), the storage modulus E′(P), and tanδ(P) of the polishing layer 101 obtained by the measurement in the bending mode in the dynamic mechanical analysis were achieved by measurement conducted on a test piece formed of the same material as that of the polishing layer 101.

As will be described later, the sealing part 106 is formed by curing, through light irradiation, a material which is applied to the outer peripheral side surface of the base material layer 103 and the like and which contains a photocurable resin. That is, the sealing part 106 is formed of the material containing the photocurable resin. The sealing part 106 is preferably formed of a material containing a photocurable resin that can be bonded to the first adhesive layer 102, the base material layer 103, and the second adhesive layer 104 and is hardly separated therefrom. Forming the sealing part 106 of a material containing a photocurable resin having high adhesiveness makes it possible to prevent forming of a gap between (i) the sealing part 106 and (ii) the first adhesive layer 102, the base material layer 103, and the second adhesive layer 104. Thus, the sealing part 106, which is formed of the material containing the photocurable resin, can more reliably reduce penetration of the polishing slurry into the base material layer 103. There is no particular limitation on the resin forming the sealing part 106, provided that the resin is a photocurable resin with which the above-described properties measured by the dynamic mechanical analysis can be obtained. For example, the resin forming the sealing part 106 is an ultraviolet curable resin. The ultraviolet curable resin is, for example, an acrylic urethane-based resin. The acrylic urethane-based resin is, for example, polyfunctional urethane acrylate. Polyfunctional urethane acrylate is, for example, LUXYDIR (registered trademark) V4260 (available from DIC Corporation, 3-functional urethane acrylate). Alternatively, it is possible to use a resin material that can achieve the above-described properties in the dynamic mechanical analysis when a photocurable resin such as the above-described one is added thereto.

The diameter of the base material layer 103 is greater than the diameter of the surface plate 150. This configuration is employed in order to solve a problem that may be caused when the polishing pad 100c is bonded to the surface plate 150. Specifically, with this configuration, it is possible to prevent misalignment between the surface plate 150 and the polishing pad 100c that may occur in bonding of the polishing pad 100c to the surface plate 150. From the viewpoint of prevention of misalignment between the surface plate 150 and the polishing pad 100c that may occur in the bonding, a difference in diameter between the base material layer 103 and the surface plate 150 is preferably not less than 1 mm, more preferably not less than 2 mm, even more preferably not less than 3 mm. From the viewpoint of hardly causing separation of the polishing pad 100c from the surface plate 150, the difference is preferably not more than 20 mm, more preferably not more than 17 mm, even more preferably not more than 13 mm. The diameter of the surface plate 150 may be set in accordance with the diameter of the base material layer 103 so that the difference in diameter between the base material layer 103 and the surface plate 150 falls within the above-described range.

### Method for Manufacturing Polishing Pad 100c

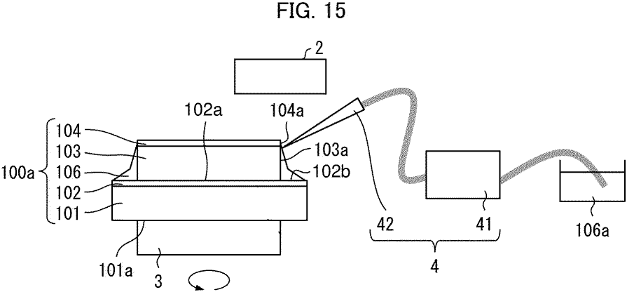

As described above, the polishing pad 100c in accordance with Embodiment 4 is configured such that the sealing part 106 is formed on the outer peripheral side surface 103a of the base material layer 103. Such a polishing pad 100c can be manufactured by applying a photocurable resin and curing, through light irradiation, the photocurable resin thus applied, as will be described later. As described above, the polishing pad 100c in accordance with Embodiment 4 is configured such that the diameter of the base material layer 103 is smaller than the diameter of the polishing layer 101. Such a polishing pad 100c can be manufactured favorably with use of the unique cutting die described in the section “Method for manufacturing polishing pad 100a” in Embodiment 1. The following description will discuss, with reference to FIGS. 14 to 15, a method for manufacturing the polishing pad 100c. FIG. 14 is a view schematically illustrating the method for manufacturing the polishing pad 100c in accordance with Embodiment 4. FIG. 15 is a view schematically illustrating an applying step in the method for manufacturing the polishing pad 100c in accordance with Embodiment 4. The method for manufacturing the polishing pad 100c in accordance with Embodiment 4 includes a laminating step, a cutting step, a removing step, and the applying step. The descriptions in the section “Method for manufacturing polishing pad 100a” are applied to the laminating step, cutting step, and removing step.

### Applying Step

The applying step is a step of applying a resin composition 106a containing a photocurable resin to the laminate (the polishing pad of Embodiment 1) 100a while carrying out light irradiation, so as to obtain the polishing pad 100c including the sealing part 106, which is a cured product of the resin composition 106a (the fifth line in FIG. 14 and FIG. 15). By applying the resin composition 106a to the laminate 100a while carrying out light irradiation, the resin composition 106a can be cured immediately after the application, before the resin composition 106a intrudes into the void in the base material layer 103. Thus, the resin composition 106a can be cured while keeping the resin composition 106a on the outer peripheral side surface 103a of the base material layer 103. If the resin composition 106a intrudes into the void in the base material layer 103 and is then cured, a resulting sealing part may not have a desired thickness or the base material layer may be exposed. The method in accordance with Embodiment 4 can prevent such phenomena, and can provide a polishing pad that can more reliably reduce penetration of the polishing slurry into the base material layer 103.

An area of the laminate 100a to which area the resin composition 106a is to be applied includes: the outer peripheral side surface 103a of the base material layer 103; the outer peripheral side surface 104a of the second adhesive layer 104; and the area 102b of the surface 102a of the first adhesive layer 102 which surface 102a is adjacent to the base material layer, the area 102b being not in contact with the base material layer 103, i.e., the area being exposed from the base material layer 103.

As shown in FIG. 15, application of the resin composition 106a is carried out by rotating a rotation table 3 on which the laminate 100a is placed in such a manner that the polishing surface 101a of the polishing layer 101 and the rotation table 3 are in contact with each other. Application of the resin composition 106a is carried out with use of an application device 4 including a pump 41 and a head 42. To be more specific, the resin composition 106a is fed to the head 42 by the pump 41, and the resin composition 106a is discharged from the head 42 so that the resin composition 106a is applied to the laminate 100a.

Light irradiation can be carried out with use of a light irradiation device 2 capable of emitting light with which a photocurable resin can be cured. The light irradiation device 2 is, for example, an ultraviolet irradiation device capable of emitting an ultraviolet ray. The ultraviolet irradiation device is, for example, a metal halide lamp. The ultraviolet ray has a wavelength of preferably not less than 200 nm and not more than 450 nm, for example.

A rotation speed may be set so as to allow reliable application of the resin composition 106a onto the laminate 100a and curing of the resin composition 106a, and is preferably not less than 0.1 rpm, more preferably not less than 1 rpm. The rotation speed is preferably not more than 10 rpm, more preferably not more than 5 rpm.

A feeding speed of the resin composition 106a may be set so as to allow reliable application of the resin composition 106a onto the laminate 100a, and is preferably not less than 0.1 g/min, more preferably not less than 1 g/min. The feeding speed of the resin composition 106a is preferably not more than 10 g/min, more preferably not more than 5 g/min.

The position of the light irradiation device 2 may be set so as to enable light irradiation to the resin composition 106a applied to the laminate 100a, and may be set so as to enable light irradiation to a part of or a whole of an area of the rotating laminate 100a on which area the resin composition 106a has been applied. Preferably, the light irradiation device 2 is positioned at a location corresponding to an area immediately after application of the resin composition 106a in a rotation direction. This makes it possible to cure the resin composition 106a before the resin composition 106a flows.

The resin composition 106a contains, in addition to the above-described photocurable resin, a diluent and a photoinitiator. A content of the photocurable resin in the resin composition 106a is preferably not less than 10 wt%, more preferably not less than 20 wt%, even more preferably not less than 30 wt%. The content is preferably not more than 70 wt%, more preferably not more than 60 wt%, even more preferably not more than 50 wt%.

The diluent is, for example, monofunctional nonylphenol acrylate. Monofunctional nonylphenol acrylate is, for example, ARONIX (registered trademark) M-111 (available from Toagosei Co., Ltd.). A content of the diluent in the photocurable resin composition is preferably not less than 30 wt%, more preferably not less than 40 wt%, even more preferably not less than 50 wt%. The content is preferably not more than 90 wt%, more preferably not more than 80 wt%, even more preferably not more than 70 wt%.

The photoinitiator is, for example, a-hydroxyalkylphenone. α-hydroxyalkylphenone is, for example, Irgacure (registered trademark) 184 (available from IGM Resins B.V.). A content of the photoinitiator in the photocurable resin composition is preferably not less than 0.1 wt%, more preferably not less than 0.3 wt%, even more preferably not less than 0.5 wt%. The content is preferably not more than 3 wt%, more preferably not more than 2 wt%, even more preferably not more than 1 wt%.

The present invention is not limited to the embodiments, but can be altered by a skilled person in the art within the scope of the claims. The present invention also encompasses, in its technical scope, any embodiment derived by combining technical means disclosed in differing embodiments.

### EXAMPLES

The following will give a description of Examples of the present invention.

### Example 1

A polishing sheet, a first adhesive sheet, a base material sheet, and a second adhesive sheet were laminated in this order. Consequently, an 815-mm square laminate pad was prepared. Used as the polishing sheet was a polishing sheet (thickness: 1.3 mm) constituted by a hard polyurethane resin (TDI-based prepolymer + aromatic diamine curing agent) to which a balloon (hollow fine particles) was internally added. Used as the first adhesive sheet was a double-sided adhesive tape (thickness: 0.1 mm) constituted by a PET base material having two surfaces made of an acrylic-based resin. Used as the base material sheet was a base material sheet (thickness: 1.3 mm, density: 0.31 g/cm³, rate of adhesion of a polyurethane resin to a nonwoven fabric: 100 wt%) constituted by a nonwoven fabric made of polyester fibers (density: 0.16 g/cm³) impregnated with a polyurethane resin. Used as the second adhesive sheet was a double-sided adhesive tape (thickness: 0.1 mm) constituted by a PET base material having two surfaces made of an acrylic-based resin.

A cutting die such as the one shown in FIGS. 3 and 4 was used to cut the laminate pad thus obtained and to make slits in the base material sheet and the second adhesive sheet. Consequently, a slit pad was obtained. The cutting die had a cutting blade with a height h1 of 2.8 mm, a first slitting blade with a height h2 of 1.4 mm, and a second slitting blade with a height of 1.4 mm. A diameter d1 of an inner periphery of the cutting blade was 762 mmφ, and a diameter d2 of an inner periphery of the first slitting blade 503 was 758 mmφ. When seen in plan view from the edge of the cutting blade, the cutting blade and the first slitting blade were arranged concentrically.

Then, from the slit pad thus obtained, portions of the base material sheet and the second adhesive sheet which portions were outward of the slit were removed. Consequently, a polishing pad was obtained. The polishing pad thus obtained included the polishing layer (diameter: 762 mmφ), the first adhesive layer (diameter: 762 mmφ), the base material layer (diameter: 758 mmφ), and the second adhesive layer (diameter: 758 mmφ) which were laminated in this order.

The obtained polishing pad was bonded, via the second adhesive layer, to a 750-mmφ surface plate included in a polishing device. The polishing pad could be easily bonded to the surface plate so that the surface plate was disposed inward of the base material layer when seen in plan view from the side of the surface plate. To be more specific, 30 times out of 30 times of the bonding work, the polishing pad could be easily bonded to the surface plate so that the surface plate was disposed inward of the base material layer. The results obtained in, among 30 times of the bonding work, the bonding works carried out with use of the polishing device for bonding the surface plate and the polishing pad to each other such that the surface plate and the polishing pad were arranged concentrically when seen in plan view from the side of the surface plate will be shown below.

### Example 2

A polishing sheet and a first adhesive sheet were laminated by a roll-to-roll process. Consequently, an upper sheet was prepared. Used as the polishing sheet was a polishing sheet (thickness: 1.3 mm) made of a hard polyurethane resin (TDI-based prepolymer + aromatic diamine curing agent) to which a balloon (hollow fine particles) was internally added. Used as the first adhesive sheet was a double-sided adhesive sheet (thickness: 0.1 mm) constituted by a PET base material having two surfaces made of an acrylic-based resin.

A base material sheet and a second adhesive sheet were laminated by a roll-to-roll process. Consequently, a lower sheet was prepared. Used as the base material sheet was a base material sheet (thickness: 1.3 mm, density: 0.31 g/cm³, rate of adhesion of a polyurethane resin to a nonwoven fabric: 100 wt%) constituted by a nonwoven fabric made of polyester fibers (density: 0.16 g/cm³) impregnated with a polyurethane resin. Used as the second adhesive sheet was a double-sided adhesive sheet (thickness: 0.1 mm) constituted by a PET base material having two surfaces made of an acrylic-based resin.

The upper sheet was cut into an 815-mm square piece. A cutting die having a diameter of 762 mmφ was used to cut the 815-mm square upper sheet to yield an upper layer (diameter: 762 mmφ, thickness: 1.4 mm) in which the polishing layer and the first adhesive layer were laminated.

A cutting die having a diameter of 756 mmφ was used to cut the lower sheet to yield a lower layer (diameter: 756 mmφ, thickness: 1.4 mm) in which the base material layer and the second adhesive layer were laminated.

A cutting die having an outer diameter of 762 mmφ and an inner diameter of 756 mmφ was used to cut a frame sheet having a thickness of 1.4 mm to yield a frame having a ring shape (outer diameter:762 mmφ, inner diameter: 756 mmφ, height: 1.4 mm). The material of the frame sheet was the same as that of the polishing sheet, except for the thickness.

The frame was fitted into a die having a hole having a diameter of 762 mmφ and a height of 3 mm. Then, the lower layer was fitted into the inside of the frame such that the base material layer was positioned on an upper side. Thereafter, the upper layer was fitted on the frame and lower layer such that the polishing layer was positioned on an upper side and the base material layer and frame were bonded to the second adhesive layer. Consequently, a polishing pad was obtained. The die was lifted so as to be separated from the polishing pad. Then, thermal pressing was carried out. The polishing pad thus obtained included the polishing layer (diameter: 762 mmφ, thickness: 1.3 mm), the first adhesive layer (diameter: 762 mmφ, thickness: 0.1 mm), the base material layer (diameter: 756 mmφ, thickness: 1.3 mm), and the second adhesive layer (diameter: 756 mmφ, thickness: 0.1 mm) which were laminated in this order. In the obtained polishing pad, the frame was in contact with (i) a peripheral portion of the base material layer, (ii) a peripheral portion of the second adhesive layer, and (iii) an area of a surface of the first adhesive layer opposite to a surface of the first adhesive layer bonded to the polishing layer, the area being not in contact with the base material layer.

The obtained polishing pad was bonded, via the second adhesive layer, to a 750-mmφ surface plate included in the polishing device. The polishing pad could be easily bonded to the surface plate so that the surface plate was disposed inward of the base material layer when seen in plan view from the side of the surface plate. To be more specific, 30 times out of 30 times of the bonding work, the polishing pad could be easily bonded to the surface plate so that the surface plate was disposed inward of the base material layer. The results obtained in, among 30 times of the bonding work, the bonding works carried out with use of the polishing device for bonding the surface plate and the polishing pad to each other such that the surface plate and the polishing pad were arranged concentrically when seen in plan view from the side of the surface plate will be shown below.

### Comparative Example 1

A cutting die having a diameter of 750 mmφ was used to cut a laminate pad obtained in a similar manner to that in Example 1. Consequently, a polishing pad constituted by layers each having a diameter of 750 mmφ was obtained.

The polishing pad thus obtained was bonded to a 750-mmφ surface plate included in a polishing device identical to the polishing device used in Example 1. The bonding was carried out such that the surface plate and the polishing pad were arranged concentrically when viewed in plan view from the side of the surface plate.

### Comparative Example 2

A polishing sheet, a first adhesive sheet, a base material sheet, and a second adhesive sheet were laminated in this order. Consequently, an 815-mm square laminate pad was prepared. Each of these sheets was made of the same material as that in Example 1. A cutting die having a diameter of 750 mmφ was used to cut the laminate pad to yield a polishing pad (diameter: 750 mmφ). The polishing pad thus obtained included the polishing layer (thickness: 1.3 mm), the first adhesive layer (thickness: 0.1 mm), the base material layer (thickness: 1.3 mm), and the second adhesive layer (thickness: 0.1 mm) which were laminated in this order.

The polishing pad thus obtained was bonded to a 750-mmφ surface plate included in a polishing device identical to the polishing device used in Example 2. The bonding was carried out such that the surface plate and the second adhesive layer were arranged concentrically.

### Example 3

A polishing sheet, a first adhesive sheet, a base material sheet, and a second adhesive sheet were laminated in this order. Consequently, an 815-mm square laminate pad was prepared. Used as the polishing sheet was a polishing sheet (thickness: 1.3 mm) made of a hard polyurethane resin (TDI-based prepolymer + aromatic diamine curing agent) to which a balloon (hollow fine particles) was internally added. Used as the first adhesive sheet was a double-sided adhesive tape (thickness: 0.1 mm) made of a PET base material having two surfaces made of an acrylic-based resin. Used as the base material sheet was a base material sheet (thickness: 1.3 mm, density: 0.31 g/cm³, rate of adhesion of a polyurethane resin to a nonwoven fabric: 100 wt%) constituted by a nonwoven fabric made of polyester fibers (density: 0.16 g/cm³) impregnated with a polyurethane resin. Used as the second adhesive sheet was a double-sided adhesive tape (thickness: 0.1 mm) constituted by a PET base material having two surfaces made of an acrylic-based resin.

A cutting die such as the one shown in FIGS. 3 and 4 was used to cut the laminate pad thus obtained and to make slits in the base material sheet and the second adhesive sheet. Consequently, a slit pad was obtained. The die had a cutting blade with a height h1 of 2.8 mm, a first slitting blade with a height h2 of 1.4 mm, and a second slitting blade with a height of 1.4 mm. The cutting blade had an inner diameter d1 of 762 mmφ, and the first slitting blade 503 had an inner diameter d2 of 758 mmφ. When seen in plan view from the edge of the cutting blade, the cutting blade and the first slitting blade were arranged concentrically.

Then, from the slit pad thus obtained, portions of the base material sheet and the second adhesive sheet which portions were outward of the slit were removed. Consequently, a laminate was obtained. The laminate thus obtained included the polishing layer (diameter: 762 mmφ), the first adhesive layer (diameter: 762 mmφ), the base material layer (diameter: 758 mmφ), and the second adhesive layer (diameter: 758 mmφ) which were laminated in this order.

Then, a resin, a diluent, and a photoinitiator were mixed at a weight ratio of 3:7:0.5 to yield a resin composition. Used as the resin was LUXYDIR (registered trademark) V4260 (available from DIC Corporation, 3-functional urethane acrylate), which is an ultraviolet curable resin. Used as the diluent was ARONIX (registered trademark) M-111 (available from Toagosei Co., Ltd.). Used as the photoinitiator was Irgacure (registered trademark) 184 (available from IGM Resins B.V.).

The resin composition was applied to the laminate while (i) carrying out irradiation of an ultraviolet ray having a wavelength of 200 nm to 450 nm with use of a metal halide lamp (Kuikkuri Metahara, available from Nichido Ind. Co., Ltd.) and (ii) rotating, at a rotation speed of 0.5 rpm, a rotation table on which the laminate was placed in such a manner that a polishing surface of the polishing layer and the rotation table were in contact with each other. The resin composition was fed to the head by the pump, and the resin composition was discharged from the head so that the resin composition was applied to the laminate. A feeding speed was 2 g/min. Specifically, the resin composition was applied to (i) an outer peripheral side surface of the base material layer, (ii) an outer peripheral side surface of the second adhesive layer, and (iii) an area of a surface of the first adhesive layer which surface is adjacent to the base material layer, the area being not in contact with the base material layer, in the laminate. Note that the metal halide lamp was positioned such that a position to be irradiated with an ultraviolet ray was at a location corresponding to an area immediately after application of the resin composition in a rotation direction.

### Comparative Example 3

The above-described laminate was used as a polishing pad of Comparative Example 3.

### Comparative Example 4

A resin composition was applied to a laminate 100a in a similar manner to Example 1, except that Comparative Example 4 did not carry out irradiation of an ultraviolet ray and used FLUOROSURF (registered trademark) FG-3650C-30 (available from Fluoro Technology Co., Ltd.) as a resin composition. A resultant was left still at room temperature (20° C.) for 3 days so that the resin composition was dried and cured. Consequently, a polishing pad was obtained.

### Comparative Example 5

A polishing pad was obtained in a similar manner identical to Comparative Example 4, except that Comparative Example 5 used FLUOROSURF (registered trademark) FS-6130 (available from Fluoro Technology Co., Ltd.) as a resin composition.

### Comparative Example 6

A polishing pad was obtained in a similar manner to Comparative Example 4, except that Comparative Example 6 used NeoCoat #33 (available from Ohtomo Chemical) as a resin composition.

Each of the polishing pads prepared in Example 3 and Comparative Examples 3 and 4 was bonded to a 750-mmφ surface plate included in a polishing device. Each of the polishing pads could be easily bonded to the surface plate so that the surface plate was disposed inward of the second adhesive layer. To be more specific, 30 times out of 30 times of the bonding work, the polishing pad could be easily bonded to the surface plate so that the surface plate was disposed inward of the periphery of the second adhesive layer. The results obtained in, among 30 times of the bonding work, the bonding works carried out with use of the polishing device for bonding the surface plate and the polishing pad to each other such that the surface plate and the second adhesive layer were arranged concentrically will be shown below.

### Polishing Test

The polishing devices prepared in Examples 1, 2, and 3 and Comparative Examples 1 and 2 were used to polish a wafer having a surface on which a thermally-oxidized film was formed. Each of the polishing device prepared in Example 1 and the polishing device prepared in Comparative Example 1 was used to polish 85 wafers. The polishing test was carried out under the following conditions.

### Polishing Conditions

Polishing pressure: 3.5 psi

Polishing slurry: CLS-9044C (1:60) (available from Planar Solutions) without H₂O₂

Dresser: Diamond dresser, model number “A188” (available from 3M)

Pad break-in conditions: 32N × 20 min, 72 rpm of rotation speed of dresser, 80 rpm of rotation speed of surface plate, 500 mL/min of feeding rate of ultrapure water Conditioning: Ex-situ, 32N, 2-scanning, 16 seconds Polishing: 85 rpm of rotation speed of surface plate, 86 rpm of rotation speed of polishing head, 200 mL/min of flow rate of polishing slurry

Polishing time: 5 minutes

After polishing, the surface plate was rotated for 5 minutes to remove moisture. Then, the polishing pad was removed from the surface plate. The polishing pad thus removed was observed from the side of the second adhesive layer to make a comparison in terms of the degree of penetration of the polishing slurry into the base material layer.

In the polishing pad of Comparative Example 1, the polishing slurry penetrated into the base material layer in an area extending for 3 cm from the edge toward the center along the entire periphery of the base material layer. On the other hand, in the polishing pad of Example 1, the polishing slurry penetrated into the base material layer in an area extending for not more than 1.5 cm from the edge toward the center. Thus, the penetration of the polishing slurry could be reduced. This reveals that the polishing pad in which the polishing layer was greater than the base material layer could reduce penetration of the polishing slurry into the base material layer, as compared to the polishing pad of Comparative Example 1 in which the polishing layer and the base material layer have the same size.

In the polishing pad of Comparative Example 2, the polishing slurry penetrated into the base material layer in an area extending for 3 cm from the edge toward the center along the entire periphery of the base material layer. On the other hand, in the polishing pad of Example 2, the polishing slurry penetrated into the base material layer in an area extending for not more than 1.0 cm from the edge toward the center. Thus, the penetration of the polishing slurry could be reduced. This reveals that the polishing pad in which the polishing layer was greater than the base material layer could reduce penetration of the polishing slurry into the base material layer, as compared to the polishing pad of Comparative Example 2 in which the polishing layer and the base material layer have the same size.

In the polishing pad of Comparative Example 3, the polishing slurry penetrated into the base material layer in an area extending for 3 cm from the edge toward the center along the entire periphery of the base material layer. In the polishing pad of Comparative Example 4, penetration of the polishing slurry into the entire periphery of the base material layer was not observed. However, penetration of the polishing slurry was observed partially in an area extending for approximately 1 cm from the edge toward the center. This is assumed to have happened as follows. That is, at the time of bonding of the sealing part of the polishing pad of Comparative Example 4 to the surface plate of the polishing layer, cracking was partially made due to low bending resistance of the sealing part, and the polishing slurry penetrated through the cracking. If such cracking is made, it is expected that capillary action would act to cause a greater amount of the polishing slurry than expected to penetrate through the cracking. On the other hand, in the polishing pad of Example 3, penetration of the polishing slurry was not observed in the entire periphery of the base material layer, and cracking in the sealing part was not observed. Thus, penetration of the polishing slurry into the base material layer could be completely prevented.

This reveals that the polishing pad in which the polishing layer was greater than the base material layer could reduce penetration of the polishing slurry into the base material layer, as compared to the polishing pad of Comparative Example 3 in which the polishing layer and the base material layer have the same size. This also reveals that the polishing pad of Example 3 could reduce penetration of the polishing slurry into the base material layer, as compared to a polishing pad obtained by applying a fluorine-based resin composition or an acrylic urethane-based resin to a laminate and curing the resin through drying, without carrying out light irradiation.

### Studies on Sealing Part

The polishing pads of Example 3 and Comparative Examples 4 to 6 were evaluated in terms of adhesiveness to the double-sided adhesive tape, adhesiveness to the base material layer, a water repelling effect of a surface of the base material layer, and a water repelling effect of a surface of the double-sided adhesive tape. Note that the water repelling effect of the surface of the base material layer was evaluated by observing states of samples when water was dripped thereto. The samples were obtained by applying the resin compositions of Example 3 and Comparative Examples 4 to 6 to the surfaces of the base material layers in the polishing pads of Example 3 and Comparative Examples 4 to 6, respectively, and curing the resin compositions thus applied. Evaluation indicators are as indicated below.

### Evaluation Indicators for Adhesiveness to Double-Sided Adhesive Tape

Excellent: Even after curing, the sealing part was not separated from the double-sided adhesive tape.

Moderate: The sealing part was bonded to the double-sided adhesive tape at the time of application of the resin composition, but was separated from the double-sided adhesive tape after curing.

Poor: The sealing part could not be bonded to the double-sided adhesive tape even at the time of application of the resin composition.

### Evaluation Indicators for Adhesiveness to Base Material Layer

Excellent: Even after curing, the sealing part was not separated from the base material layer.

Moderate: The sealing part was bonded to the base material layer at the time of application of the resin composition, but was separated from the base material layer after curing.

Poor: The sealing part could not be bonded to the base material layer even at the time of application of the resin composition.

### Evaluation Indicators for Water Repelling Effect Of Surface of Base Material Layer

Excellent: Even after lapse of 24 hours since start of dripping of water, penetration of water into the base material layer was not observed.

Moderate: Penetration of water into the base material layer was observed over time since start of dripping of water.

Poor: Penetration of water into the base material layer was observed immediately after dripping of water.

### Water Repelling Effect of Surface of Double-Sided Adhesive Tape

Excellent: Even after elapse of 24 hours since start of dripping of water, penetration of water into the base material layer was not observed.

Moderate: Penetration of water into the base material layer was observed over time since start of dripping of water. Poor: Penetration of water into the base material layer was observed immediately after dripping of water.

The results of the evaluations are shown in Table 1.

TABLE 1

| | Ex. 3*¹ | C. Ex. 4*² | C. Ex. 5*² | C. Ex. 6*² |
|---|---|---|---|---|
| Resin material | LUXYDIR V4260 | FLUOROSURF FG-3650C-30 | FLUOROSURF FS-6130 | NeoCoat #33 |
| Kind of resin | Ultraviolet curable acrylic urethane-based resin | Fluorine-based resin | Fluorine-based resin | Urethane-based resin |
| Kind of solvent in resin material | - | Fluorine-based solvent | Water, ethanol, isopropyl alcohol | Water |
| Diluent | ARONIX M-111 | - | - | - |
| Photoinitiator | Irgacure 184 | - | - | - |
| Color | Transparent | Transparent | Transparent | White |
| Viscosity (mPa·s) | 3000 | 100 | Not more than 100 | Not more than 100 |
| Formation of coating on double-sided adhesive tape | Good | Good | Good | Drying needed |
| Adhesiveness to double-sided adhesive tape | Excellent | Excellent | Poor | Excellent |
| Adhesiveness to base material layer | Excellent | Excellent | Poor | Moderate |
| Water repelling effect in surface of base material layer | Excellent | Excellent | Excellent | Poor |
| Water repelling effect in surface of double-sided adhesive tape | Excellent | Excellent | Excellent | Poor |

*1: “Ex.” stands for “Example”. *2: “C. Ex.” stands for “Comparative Example”.

### Measurement in Bending Mode in Dynamic Mechanical Analysis

For the resin compositions used for the sealing parts of Examples and Comparative Examples and the polishing layers of Examples and Comparative Examples, samples of 5 cm in vertical width, 0.5 cm in horizontal width, and 0.125 cm in thickness were prepared. The samples thus prepared were subjected to measurement in the bending mode in the dynamic mechanical analysis. The measurement were carried out under the following conditions. The results of the measurement in the bending mode in the dynamic mechanical analysis are shown in Table 2.

### Measurement Conditions

Measuring device: RSA3 (available from TA Instruments) Sample: 5 cm in vertical width, 0.5 cm in horizontal width, and 0.125 cm in thickness
Test length: -
Pre-treatment on sample: Maintained for 40 hours at a temperature of 23° C. and a relative humidity of 50%.
Test mode: bending
Frequency: 0.16 Hz (1 rad/sec)
Temperature range: 30 to 50° C.
Temperature increase rate: 1.5° C./min
Strain range: 0.30%
Initial load: -

Measurement interval: 2 point/°C

TABLE 2

| | Polishing layer | Ex. 3*¹ | C. Ex. 4*² | C. Ex. 5*² | C. Ex. 6*² |
|---|---|---|---|---|---|
| Loss modulus E″(MPa) at 40° C. | 24.9 | 42.8 | 0.82 | 0.76 | 7.53 |
| E″(S)/E″(P) | - | 1.72 | 0.033 | 0.031 | 0.302 |
| Storage modulus E′(MPa) at 40° C. | 226.7 | 72.0 | 10.9 | 9.7 | 53.8 |
| E′(S) / E′(P) | - | 0.32 | 0.048 | 0.043 | 0.237 |
| tanδ at 40° C. | 0.110 | 0.594 | 0.075 | 0.078 | 0.140 |
| tanδ (S) / tanδ (P) | - | 5.40 | 0.68 | 0.71 | 1.28 |

*1: “Ex.” stands for “Example”. *2: “C. Ex.” stands for “Comparative Example”.

The loss modulus E″(P), the storage modulus E′(P), and tanδ(P) at 40° C. of each of the polishing layers used in the Examples and Comparative Examples were 24.9 (MPa), 226.7 (MPa), and 0.110, respectively. Note that generally-used polishing layers have a loss modulus E″(P) at 40° C. of 10 MPa to 100 MPa, a storage modulus E′(P) at 40° C. of 100 MPa to 1000 MPa, and tanδ(P) at 40° C. of 0.05 to 0.20.

Example 3 exhibited a loss modulus E″(S), a storage modulus E′(S), and tanδ(S) at 40° C. all higher than those of Comparative Examples 4 to 6. Particularly, in Example 3, the loss modulus E″(S) was higher than the loss modulus E″(P) of the polishing layer. It is considered that a sealing part has a bending resistance when the sealing part has a loss modulus E″(S) at 40° C. which is 1 to 10 times greater than a loss modulus E″(P) of a polishing layer. Note that a sample that (i) employed the same kind of photocurable resin as that of Example 3, (ii) exhibited a storage modulus E′(P) (approximately 200 MPa) at 40° C. which was substantially equal to the storage modulus E′(S) at 40° C. of the polishing layer, and (iii) exhibited a loss modulus E″(S) at 40° C. which was 120 MPa also had bending resistance, similarly to Example 3.

### INDUSTRIAL APPLICABILITY

A polishing pad or a polishing unit in accordance with an aspect of the present invention is usable to polish, e.g., optical materials, semiconductor devices, and substrates for hard disk, and, particularly, is suitably usable to polish devices including a semiconductor wafer having an oxide layer, a metal layer, and/or the like formed thereon.

### REFERENCE SIGNS LIST

1: polishing device
2: light irradiation device
3: rotation table
4: application device
10a, 10b, 10c: polishing unit
20: holding unit
30: polishing slurry feeding section
40: polished material
41: pump
42: head
50: cutting die
100a, 100b, 100c, 100d: polishing pad
101: polishing layer
102: first adhesive layer
103: base material layer
104: second adhesive layer
105: frame
106 sealing part
106a: resin composition
110: laminate pad
111 polishing sheet
112: first adhesive sheet
113: base material sheet
114: second adhesive sheet
120: slit pad
130: upper layer
140, 240: lower layer
150: surface plate
501: substrate
502: cutting blade
503: first slitting blade (slitting blade)
504: second slitting blade

1. A polishing pad comprising:
a polishing layer;
a first adhesive layer;
a base material layer including a nonwoven fabric; and
a second adhesive layer,
the polishing layer, the first adhesive layer, the base material layer, and the second adhesive layer being laminated in this order so as to be arranged concentrically,
the base material layer having a diameter smaller than a diameter of the polishing layer.

2. A polishing pad comprising:
a polishing layer;
a base material layer including a nonwoven fabric;
a first adhesive layer; and
a frame having a ring shape,
the polishing layer and the base material layer being bonded to each other via the first adhesive layer,
the base material layer having a diameter smaller than a diameter of the polishing layer,
the frame having a ring shape covering an outer peripheral side surface of the base material layer.

3. The polishing pad as set forth in claim 2, wherein:
the frame does not have a void communicated with an outer peripheral side surface and an inner peripheral surface of the frame.

4. The polishing pad as set forth in claim 2, wherein:
the frame is made of a material identical to a material of the polishing layer.

5. The polishing pad as set forth in claim 2, wherein:
a difference in diameter between the base material layer and the polishing layer is not less than 1 mm and not more than 10 mm.

6. The polishing pad as set forth in claim 2, further comprising:
a second adhesive layer provided on a surface of the base material layer opposite to a surface of the base material layer adjacent to the polishing layer, wherein
the frame further covers an outer peripheral side surface of the second adhesive layer.

7. The polishing pad as set forth in claim 6, wherein:
the frame has a height that is equal to a sum of a thickness of the base material layer and a thickness of the second adhesive layer.

8. A polishing pad comprising:
a polishing layer;
a base material layer including a nonwoven fabric; and
a first adhesive layer,
the polishing layer and the base material layer being bonded to each other via the first adhesive layer,
the base material layer having a diameter smaller than a diameter of the polishing layer,
a sealing part made of a material containing a photocurable resin covering (i) an outer peripheral side surface of the base material layer and (ii) an area of a surface of the adhesive layer which surface is adjacent to the base material layer, the area being not in contact with the base material layer,
a loss modulus E″(S) at 40° C. of the sealing part, measured in a bending mode in a dynamic mechanical analysis at a frequency of 0.16 Hz, being 1 to 10 times greater than a loss modulus E″(P) of the polishing layer.

9. The polishing pad as set forth in claim 8, wherein:
the loss modulus E″(S) at 40° C. of the sealing part is 10 MPa to 1000 MPa.

10. The polishing pad as set forth in claim 8, wherein:
a storage modulus E′(S) at 40° C. of the sealing part, measured in the bending mode in the dynamic mechanical analysis at a frequency of 0.16 Hz, is 0.1 to 10 times greater than a storage modulus E′(P) at 40° C. of the polishing layer.

11. The polishing pad as set forth in claim 8, wherein:
the storage modulus E′(S) at 40° C. of the sealing part is 10 MPa to 5000 MPa.

12. (canceled)

13. (canceled)

14. A polishing unit comprising:
a polishing pad; and
a surface plate, wherein:
the polishing pad includes a polishing layer, a first adhesive layer, a base material layer including a nonwoven fabric, and a second adhesive layer which are laminated in this order;
the polishing pad is bonded to the surface plate via the second adhesive layer;
the base material layer has a diameter that is smaller than a diameter of the polishing layer and that is greater than a diameter of the surface plate; and
when seen in plan view from a side of the surface plate, the base material layer is disposed inward of the polishing layer and the surface plate is disposed inward of the base material layer.

15. The polishing unit as set forth in claim 14, wherein:
a difference in diameter between the base material layer and the surface plate is not less than 1 mm and not more than 20 mm.

16. (canceled)

17. The polishing unit as set forth in claim 14, wherein:
the polishing pad further includes a frame having a ring shape or a sealing part, the frame or the sealing part surrounding an outer peripheral side surface of the base material layer and an outer peripheral side surface of the second adhesive layer; and
the frame or the sealing part covers (i) the outer peripheral side surface of the base material layer, (ii) the outer peripheral side surface of the second adhesive layer, and (iii) an area of a surface of the first adhesive layer which surface is adjacent to the base material layer, the area being not in contact with the base material layer.

18. (canceled)

19. A polishing device comprising a polishing unit recited in claims 14.

20. (canceled)

21. (canceled)

22. A method for manufacturing a polishing pad recited in claim 7, comprising:
an upper layer production step of obtaining an upper layer by cutting, into a shape of the polishing layer, an upper sheet constituted by a polishing sheet and a first adhesive sheet laminated to each other;
a lower layer production step of obtaining a lower layer by cutting, into a shape of the base material layer, a lower sheet constituted by a base material sheet containing a nonwoven fabric and a second adhesive sheet laminated to each other;
a frame preparation step of preparing a frame having a ring shape having an inner diameter equal to an outer diameter of the base material layer; and
a bonding step of obtaining a polishing pad by fitting the lower layer into an inside of the frame and bonding the frame and the lower layer to the upper layer so that the base material layer and the frame are bonded to the first adhesive layer.

23. The method as set forth in claim 22, wherein:
the polishing pad is configured such that the diameter of the polishing layer is equal to an outer diameter of the frame;
the bonding step is carried out with use of a die having a hole having (i) a diameter equal to the outer diameter of the frame and a diameter of the upper layer and (ii) a height not less than a thickness of the lower layer; and
in the bonding step, (i) the frame is fitted into the hole, the lower layer is fitted into the inside of the frame, and then the upper layer is fitted into the hole or (ii) the upper layer and the frame are fitted into the hole of the die in this order and then the lower layer is fitted into the inside of the frame.

24. The method as set forth in claim 22, wherein:
the polishing pad is configured such that the outer diameter of the frame is smaller than the diameter of the polishing layer;
the bonding step is carried out with use of a die having a hole constituted by (i) a first fitting part having a diameter equal to the diameter of the frame and a height not more than a thickness of the lower layer and (ii) a second fitting part having a diameter equal to a diameter of the upper layer, the first fitting part and the second fitting part being arranged side by side in a height direction, an overall height of the hole being not less than the thickness of the lower layer; and
in the bonding step, the frame is fitted into the first fitting part of the hole, the lower layer is fitted into an inside of the frame, and then the upper layer is fitted into the second fitting part of the hole.

25. A method for manufacturing a polishing pad recited in claims 8, comprising:
forming the sealing part by carrying out application of a photocurable resin while curing, through light irradiation, the photocurable resin thus applied, the application being carried out such that the photocurable resin is applied onto (i) an outer peripheral side surface of the base material layer and (ii) an area of a surface of the first adhesive layer which surface is adjacent to the base material layer, the area being not in contact with the base material layer.

26. The method as set forth in claim 25, wherein:
the light is an ultraviolet ray; and
the photocurable resin is an ultraviolet curable acrylic urethane-based resin.
